(19) United States
(12) Patent Application Publication
(10) Pub. No.: US 2024/0186196 A1
(43) Pub. Date: Jun. 6, 2024

(54) ELECTRONIC COMPONENT

(71) Applicant: ROHM CO., LTD., Kyoto (JP)

(72) Inventors: Bungo TANAKA, Kyoto (JP); Yuta KASHITANI, Kyoto (JP); Toshiyuki KANAYA, Kyoto (JP); Keiji WADA, Kyoto (JP); Genki MATSUYAMA, Kyoto (JP)

(73) Assignee: ROHM CO., LTD., Kyoto (JP)

(21) Appl. No.: 18/442,283

(22) Filed: Feb. 15, 2024

Related U.S. Application Data
(63) Continuation of application No. PCT/JP2022/031394, filed on Aug. 19, 2022.

(30) Foreign Application Priority Data
Aug. 26, 2021 (JP) 2021-138330
Aug. 26, 2021 (JP) 2021-138331

(51) Int. Cl. H01L 23/14

(52) U.S. Cl. CPC H01L 23/145

(57) ABSTRACT

An electronic component includes an underlay resin, and a pad electrode that has a sidewall located on the underlay resin and an uneven portion formed at a lower end portion of the sidewall.

### CROSS REFERENCE TO RELATED APPLICATIONS

The present application is a bypass continuation of International Patent Application No. PCT/JP2022/031394, filed on Aug. 19, 2022, which claims priority to Japanese Patent Application No. 2021-138330 filed in the Japan Patent Office on Aug. 26, 2021 and Japanese Patent Application No. 2021-138331 filed in the Japan Patent Office on Aug. 26, 2021, the entire disclosures of these applications are incorporated herein by reference.

### BACKGROUND

### 1. Field of the Disclosure

The present disclosure relates to an electronic component.

### 2. Description of the Related Art

US2013/0221520A1 discloses an electronic component including an electrode pad, a polyimide layer, and a Cu pillar. The polyimide layer partially covers the electrode pad. The Cu pillar is arranged on the electrode pad, and covers the polyimide layer.

### BRIEF DESCRIPTION OF THE DRAWINGS

FIG. 1 is a perspective view showing a package in which an electronic component according to a first embodiment is mounted.

FIG. 2 is a plan view showing the package of FIG. 1 seen from a mounting surface side.

FIG. 3 is a plan view showing an internal structure of the package of FIG. 1 seen from a non-mounting surface side.

FIG. 4 is a cross-sectional view along line IV-IV of FIG. 3.

FIG. 5 is an enlarged view of a region V of FIG. 4.

FIG. 6A is an enlarged view of a part of a top wiring of FIG. 5.

FIG. 6B is an enlarged view of a part of a pad structure of FIG. 5.

FIG. 7 is a graph showing a relationship between the thickness of a wiring electrode and stress.

FIG. 8 is a graph showing a relationship between the thickness of a first metal film and stress.

FIG. 9 is a graph showing a relationship between the overlap width of an underlay resin film and stress.

FIG. 10 is a graph showing a relationship between the thickness of the underlay resin film and stress.

FIGS. 11A to 11S are cross-sectional views showing an example of a method of manufacturing the package of FIG. 1.

FIG. 12 corresponds to FIG. 5, and is a cross-sectional view showing an electronic component according to a second embodiment.

FIGS. 13A to 13G are cross-sectional views showing an example of a process of manufacturing the electronic component of FIG. 12.

FIG. 14 corresponds to FIG. 4, and is a cross-sectional view showing a package in which an electronic component according to a third embodiment is mounted.

FIG. 15 is an enlarged view of a region XV of FIG. 14.

### DETAILED DESCRIPTION OF THE PREFERRED EMBODIMENTS

Embodiments will be hereinafter described in detail. The accompanying drawings are schematic views, and are not necessarily strictly shown, and do not necessarily coincide with each other in scale and the like. Hatching is given to some plan views among the accompanying drawings in order to clarify each structure. The same reference sign is assigned to a constituent that corresponds to each constituent in the accompanying drawings, and a duplicated description of this constituent is omitted or simplified. A description of a constituent, which has not yet been omitted or simplified, is applied to a corresponding constituent a description of which has been omitted or simplified.

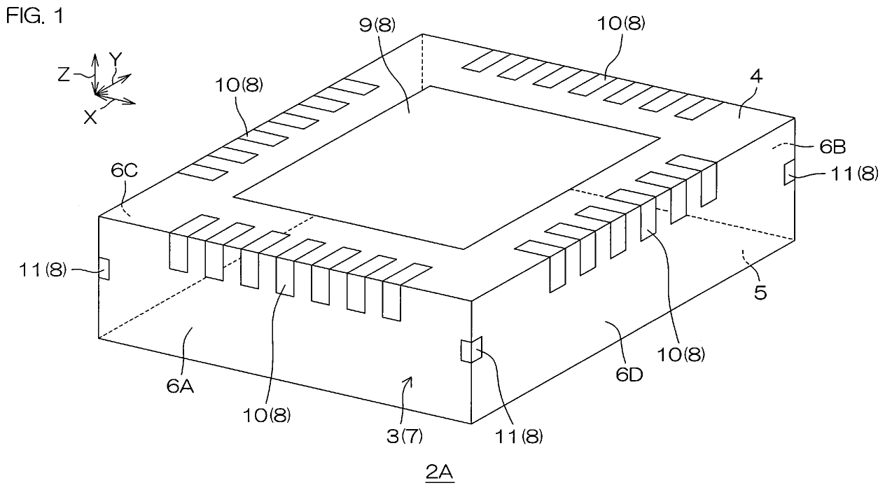

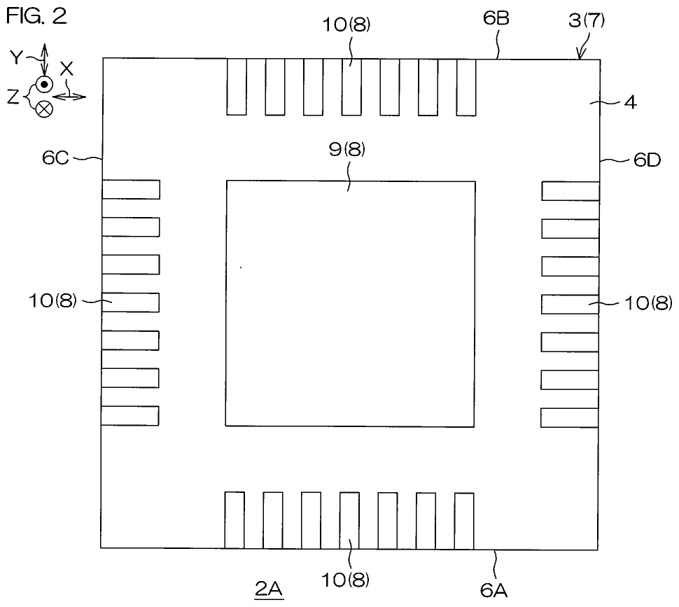

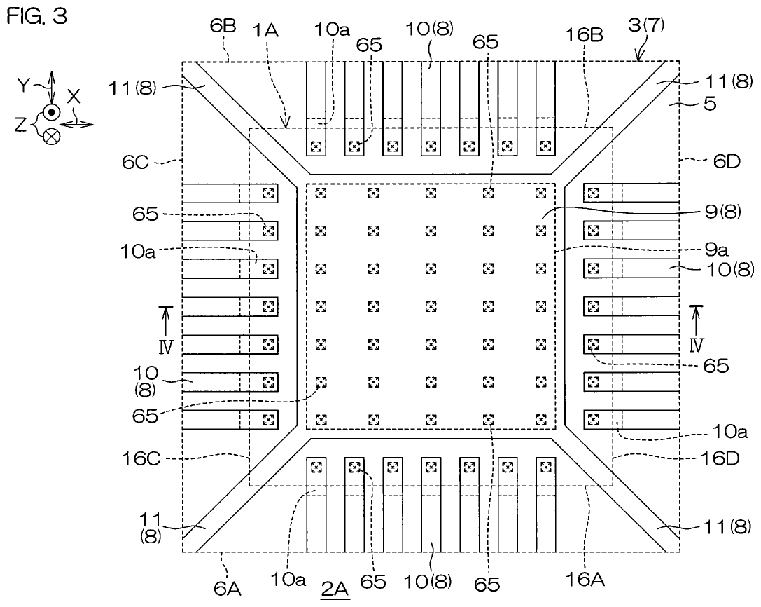

FIG. 1 is a perspective view showing a package 2A in which an electronic component 1A according to a first embodiment is mounted. FIG. 2 is a plan view showing the package 2A of FIG. 1 seen from a mounting surface 4 side. FIG. 3 is a plan view showing an internal structure of the package 2A of FIG. 1 seen from a non-mounting surface 5 side.

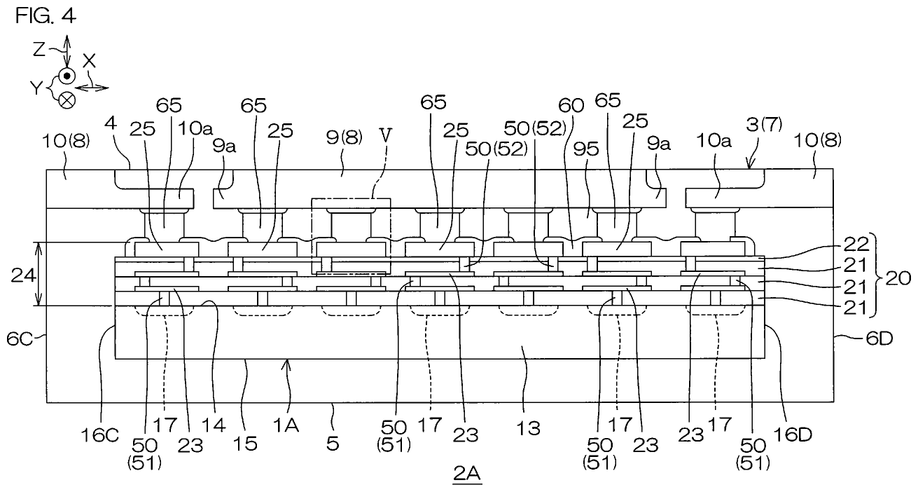

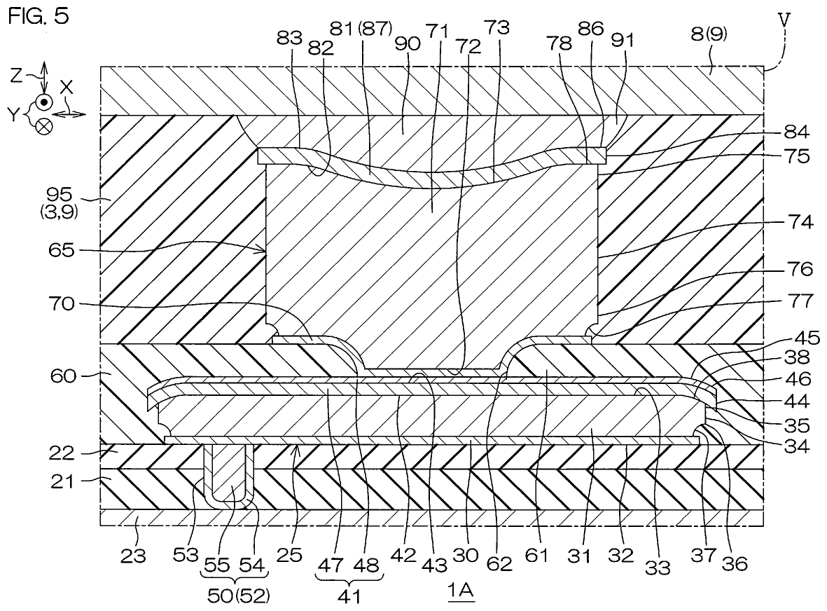

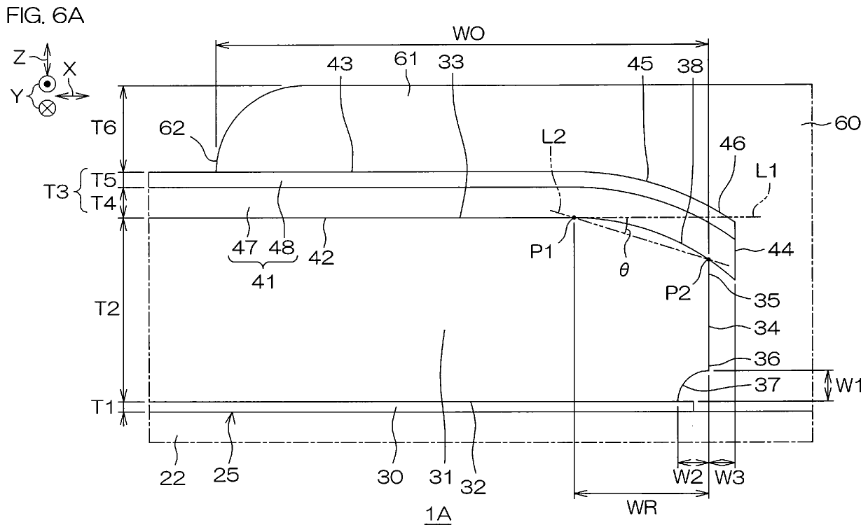

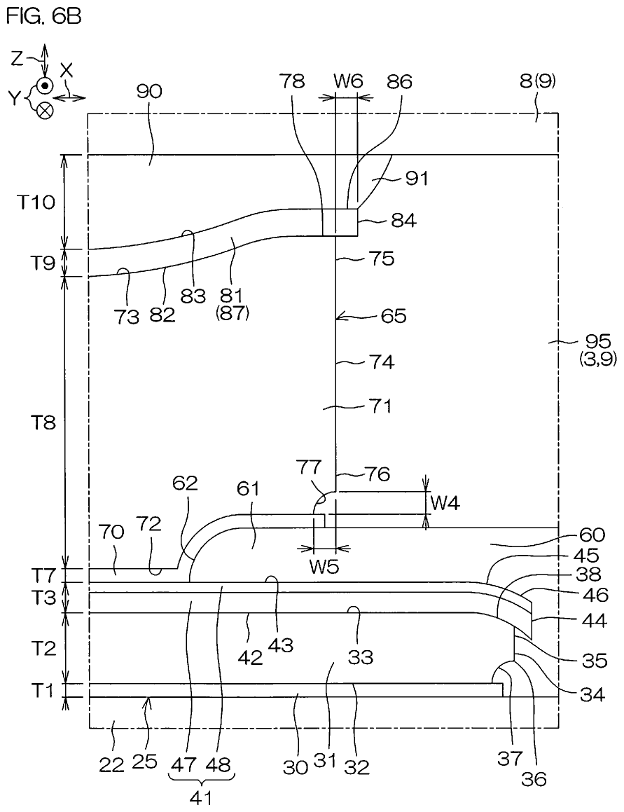

FIG. 4 is a cross-sectional view along line IV-IV of FIG. 3. FIG. 5 is an enlarged view of a region V of FIG. 4. FIG. 6A is an enlarged view of a part of a top wiring 25 of FIG. 5. FIG. 6B is an enlarged view of a part of a pad structure 65 of FIG. 5. For clarity, hatching is omitted in FIG. 6A and FIG. 6B.

Referring to FIG. 1 to FIG. 4, the package 2A is a QFN (Quad Flat Non-leaded) type package in this embodiment. The package 2A includes a package body 3 having a hexahedral shape (in this embodiment, rectangular parallelepiped shape). The package body 3 has the mounting surface 4 on one side, the non-mounting surface 5 on the other side, and first to fourth sidewalls 6A to 6D connecting the mounting surface 4 and the non-mounting surface 5.

The mounting surface 4 and the non-mounting surface 5 are each formed in a quadrangular shape in a plan view seen from their normal directions Z (hereinafter, referred to simply as a “plan view”). The first to fourth sidewalls 6A to 6D vertically extend along the normal direction Z. The first sidewall 6A and the second sidewall 6B extend in a first direction X along the mounting surface 4, and face a second direction Y that intersects (in detail, perpendicularly intersects) the first direction X. The third sidewall 6C and the fourth sidewall 6D extend in the second direction Y, and face the first direction X.

The package body 3 includes a molding resin 7. The molding resin 7 includes a matrix resin and a plurality of fillers. The matrix resin may include a thermosetting resin (for example, epoxy resin). The matrix resin may be colored by a coloring material such as carbon black. In other words, the molding resin 7 may be an opaque resin.

The fillers are each made of a spherical substance made of ceramic, oxide, insulator, or the like. In this embodiment, the fillers are each made of silicon oxide particles (silica particles). Preferably, the molding resin 7 includes a plurality of fillers that differ from each other in particle diameter (particle size).

The package 2A includes a conductive plate 8 arranged inside the package body 3. The conductive plate 8 may be referred to as a “lead frame.” In this embodiment, the conductive plate 8 includes a die pad portion 9, at least one lead portion 10 (in this embodiment, a plurality of lead portions 10), and at least one finger portion 11 (in this embodiment, a plurality of finger portions 11). The number of the lead portions 10 is arbitrary. The presence or absence of the finger portion 11 is arbitrary, and the conductive plate 8 that does not include the finger portion 11 may be employed.

The die pad portion 9 is arranged at a central portion of the package body 3 so as to be exposed from the mounting surface 4. In this embodiment, the die pad portion 9 is formed in a polygonal shape (in detail, quadrangular shape) having four sides parallel to the first to fourth sidewalls 6A to 6D in a plan view. The planar shape of the die pad portion 9 is arbitrary. The die pad portion 9 has a projection portion 9a that projects toward the first to fourth sidewalls 6A to 6D in a peripheral edge end portion on the non-mounting surface 5 side.

The lead portions 10 are arranged at a peripheral edge portion of the package body 3 at a distance from the die pad portion 9 so as to be exposed from the mounting surface 4. The lead portions 10 may be arranged along at least one among the first to fourth sidewalls 6A to 6D. In this embodiment, the plurality of lead portions 10 (in this embodiment, seven lead portions 10) are arranged along each of the first to fourth sidewalls 6A to 6D, and are exposed from the corresponding first to fourth sidewalls 6A to 6D, respectively.

In this embodiment, the lead portions 10 are each formed in a belt shape extending in a direction perpendicular to the corresponding first to fourth sidewalls 6A to 6D in a plan view. The planar shape of the lead portions 10 is arbitrary. The lead portions 10 have a projection portion 10a that projects toward the die pad portion 9 side (projection portion 9a side) in the peripheral edge end portion on the non-mounting surface 5 side.

The finger portions 11 are each led out from the die pad portion 9 toward the peripheral edge (first to fourth sidewalls 6A to 6D) of the package body 3 in a plan view. In other words, the finger portions 11 are fixed at the same potential as the die pad portion 9. In this embodiment, the finger portions 11 are each led out from four corners of the die pad portion 9 toward four corners of the package body 3, and are exposed from the four corners of the package body 3 in a plan view.

The package 2A includes the electronic component 1A arranged inside the package body 3 so as to be electrically connected to the conductive plate 8. The electronic component 1A is arranged in a region located on the non-mounting surface 5 side with respect to the conductive plate 8 so as not to be exposed from the package body 3. In other words, the whole area of an outer surface of the electronic component 1A is covered with the molding resin 7. In this embodiment, the electronic component 1A is mechanically and electrically connected to the conductive plate 8 according to a flip chip connection mode.

In this embodiment, the electronic component 1A is arranged inside the package body 3 so as to overlap with the whole area of the die pad portion 9, with end portions of the lead portions 10, and with the finger portions 11 in a plan view. The electronic component 1A is mechanically and electrically connected to the die pad portion 9 and to the end portions of the lead portions 10, and is not mechanically connected to the finger portions 11. A detailed structure of the electronic component 1A, which is in a state of being mounted in the package 2A, will be hereinafter described.

The electronic component 1A is a semiconductor device including a semiconductor chip 13 (chip). The semiconductor chip 13 may include at least either one of silicon and a wide bandgap semiconductor. The wide bandgap semiconductor is a semiconductor having a bandgap exceeding the bandgap of silicon.

Gallium nitride, silicon carbide, diamond, etc., can be exemplified as the wide bandgap semiconductor. In this embodiment, the semiconductor chip 13 is a silicon chip. The semiconductor chip 13 may have a laminated structure including a semiconductor substrate and an epitaxial layer. The semiconductor chip 13 may have a single layer structure consisting of a semiconductor substrate or an epitaxial layer.

The semiconductor chip 13 has a first main surface 14 on one side, a second main surface 15 on the other side, and first to fourth side surfaces 16A to 16D connecting the first main surface 14 and the second main surface 15. The first main surface 14 may be referred to as a “terminal surface” or a “device surface.” The second main surface 15 may be referred to as a “non-terminal surface” or a “non-device surface.”

The first main surface 14 and the second main surface 15 are each formed in a quadrangular shape in a plan view. The first side surface 16A and the second side surface 16B extend in the first direction X, and face the second direction Y. The third side surface 16C and the fourth side surface 16D extend in the second direction Y, and face the first direction X. The semiconductor chip 13 is arranged on the non-mounting surface 5 side with respect to the conductive plate 8 in an orientation in which the first main surface 14 faces the conductive plate 8.

The electronic component 1A includes a plurality of device regions 17 divisionally formed in the first main surface 14. In FIG. 4, the device regions 17 are each shown with a broken line. The number and the arrangement of the device regions 17 are arbitrary. The device regions 17 respectively include functional devices formed by utilizing regions inside and outside the semiconductor chip 13.

The functional device may include at least one among a semiconductor switching device, a semiconductor rectifying device, and a passive device. The functional device may include a circuit network in which at least two among a semiconductor switching device, a semiconductor rectifying device, and a passive device are combined.

The semiconductor switching device may include at least one among MISFET (Metal Insulator Semiconductor Field Effect Transistor), BJT (Bipolar Junction Transistor), IGBT (Insulated Gate Bipolar Junction Transistor), and JFET (Junction Field Effect Transistor).

The semiconductor rectifying device may include at least one among a pn junction diode, a pin junction diode, a Zener diode, a Schottky barrier diode, and a fast recovery diode. The passive device may include at least one among a resistor, a capacitor, an inductor, and a fuse.

The electronic component 1A includes an insulation layer 20 formed on the first main surface 14. In other words, the insulation layer 20 is interposed between the conductive plate 8 and the first main surface 14. In this embodiment, the insulation layer 20 covers the whole area of the first main surface 14 in a plan view, and is continuous with the peripheral edge (first to fourth side surfaces 16A to 16D) of the semiconductor chip 13. The insulation layer 20 includes a plurality of interlayer insulation films 21 and a top insulation film 22 (to-be-covered object).

The number of laminated layers of the interlayer insulation films 21 is arbitrary. As an example, the number of laminated layers of the interlayer insulation films 21 may be not less than two and not more than twenty-five. The interlayer insulation films 21 may each have a single layer structure or a laminated structure including at least either one of a silicon oxide film and a silicon nitride film. In this embodiment, the interlayer insulation films 21 each have a single layer structure consisting of a silicon oxide film.

The top insulation film 22 forms a terminal insulation film of the insulation layer 20, and covers the uppermost interlayer insulation film 21. The top insulation film 22 may be referred to as an “inorganic insulation film” or a “passivation film.” The top insulation film 22 may have a single layer structure including at least either one of a silicon oxide film and a silicon nitride film.

Preferably, the top insulation film 22 includes an insulation material differing from, at least, that of the uppermost interlayer insulation film 21. In this embodiment, the top insulation film 22 has a single layer structure consisting of a silicon nitride film. The top insulation film 22 has a flat surface extending along the first main surface 14. Preferably, the top insulation film 22 has a thickness less than, at least, the thickness of the uppermost interlayer insulation film 21. In this embodiment, the thickness of the top insulation film 22 is less than the thickness of each of the interlayer insulation films 21.

The electronic component 1A includes a plurality of interlayer wirings 23 arranged inside the insulation layer 20. The interlayer wirings 23 are wiring films arranged on the arbitrary interlayer insulation film 21 in a lower layer positioned below the top insulation film 22. The form of routing around the interlayer wirings 23 is arbitrary. The interlayer wirings 23 form a multilayer wiring structure 24 (to-be-covered object) with the interlayer insulation films 21.

The interlayer wirings 23 may include at least either one of an Al-based metal film and a Cu-based metal film. The interlayer wirings 23 may include at least one among a pure Al film (Al film whose purity is equal to or more than 99%), a pure Cu film (Cu film whose purity is equal to or more than 99%), an AlCu alloy film, an AlSi alloy film, and an AlSiCu alloy film.

The electronic component 1A includes a plurality of top wirings 25 arranged on the insulation layer 20 (in detail, on the top insulation film 22). The top wirings 25 each form a terminal wiring of the multilayer wiring structure 24. The mode of routing around the top wirings 25 is arbitrary. The top wirings 25 may be linearly routed around, or may be formed in an island shape in a plan view. As a matter of course, the top wirings 25 may have a comparatively wide island portion and a comparatively narrow line portion linearly led out from the island portion in a plan view.

The top wirings 25 each have a thickness exceeding the thickness of the top insulation film 22. Preferably, the top wirings 25 each have a thickness exceeding the thickness of each of the interlayer wirings 23. Preferably, the top wirings 25 have a thickness less than the thickness of a part of the fillers included in the molding resin 7. The wiring layers have the same configuration except the arrangement place and the mode of routed around. The structure of the single top wiring 25 will be hereinafter described in detail.

Referring to FIG. 5 and FIG. 6A, the top wiring 25 includes a wiring barrier film 30 that selectively covers the top insulation film 22. The wiring barrier film 30 extends substantially flat along the top insulation film 22. The wiring barrier film 30 is a high-hardness metal film having a comparatively-small thermal expansion coefficient. The thermal expansion coefficient of the wiring barrier film 30 may be not less than 4 μm/m·K and not more than 9 μm/m·K.

Preferably, the wiring barrier film 30 includes at least one among a Ti film, a TiN film, a Ta film, a W film, a Mo film, a Cr film, and a Ru film. Preferably, the wiring barrier film 30 includes a Ti-based metal. The wiring barrier film 30 may have a laminated structure or a single layer structure including at least either one of a Ti film and a TiN film. The wiring barrier film 30 may have a laminated structure including a Ti film and a TiN film that are laminated in that order from the top insulation film 22 side. In this embodiment, the wiring barrier film 30 has a single layer structure consisting of a Ti film.

The wiring barrier film 30 has a first thickness T1 with respect to a laminated direction. The laminated direction is the normal direction Z (hereinafter, the same applies). The first thickness T1 may be not less than 0.01 μm and not more than 0.5 μm. Preferably, the first thickness T1 is not less than 0.05 μm and not more than 0.2 μm.

The top wiring 25 includes a wiring electrode 31 covering the wiring barrier film 30. The wiring electrode 31 forms a main body of the top wiring 25. The wiring electrode 31 includes a metal film differing from the wiring barrier film 30. In detail, the wiring electrode 31 includes a low-hardness metal film having a thermal expansion coefficient exceeding the thermal expansion coefficient of the wiring barrier film 30.

The wiring electrode 31 may include at least either one of an Al-based metal film and a Cu-based metal film. The wiring electrode 31 may include at least one among a pure Al film (Al film whose purity is equal to or more than 99%), a pure Cu film (Cu film whose purity is equal to or more than 99%), an AlCu alloy film, an AlSi alloy film, and an AlSiCu alloy film. Preferably, the wiring electrode 31 is made of a Cu-based metal film. In this embodiment, the wiring electrode 31 is made of a pure Cu film.

In this embodiment, the thermal expansion coefficient of the wiring electrode 31 is about 16.5 μm/m·K. The wiring electrode 31 has a second thickness T2 (T1<T2) exceeding the first thickness T1 of the wiring barrier film 30 with respect to the laminated direction. The second thickness T2 may be not less than 1 μm and not more than 15 μm.

The wiring electrode 31 covers the whole area of the wiring barrier film 30 in a cross-sectional view and in a plan view. In this embodiment, the wiring electrode 31 has a peripheral edge portion that projects to a region located outside the wiring barrier film 30 so as to face the top insulation film 22 in the laminated direction.

The wiring electrode 31 includes a wiring lower surface 32, a wiring upper surface 33, and a wiring sidewall 34. The wiring lower surface 32 extends substantially flat along the wiring barrier film 30. The wiring upper surface 33 extends substantially flat along the wiring barrier film 30. The wiring sidewall 34 is placed on the top insulation film 22, and extends substantially vertically in the laminated direction. The term “substantially vertically” also includes a form in which it extends in the laminated direction while curving (meandering). The wiring sidewall 34 is placed in a region located outside the wiring barrier film 30, and faces the top insulation film 22 without the wiring barrier film 30 between the wiring sidewall 34 and the top insulation film 22 in the laminated direction.

The wiring sidewall 34 has a wiring upper end portion 35 on the wiring upper surface 33 side and a wiring lower end portion 36 on the top insulation film 22 side. The wiring sidewall 34 has a wiring recessed portion 37 that is inwardly hollowed in the wiring lower end portion 36. The wiring recessed portion 37 forms an uneven portion (wiring uneven portion) in the wiring lower end portion 36. The wiring recessed portion 37 may be hollowed inward than the wiring upper end portion 35. The wiring recessed portion 37 may be hollowed in a curved shape.

The wiring recessed portion 37 exposes a peripheral edge portion of the wiring barrier film 30. In detail, the wiring recessed portion 37 has an upper end portion placed outward from the peripheral edge of the wiring barrier film 30 and a lower end portion placed inward from the peripheral edge of the wiring barrier film 30. In this embodiment, the wiring recessed portion 37 also exposes the top insulation film 22. The wiring recessed portion 37 is formed at a distance from an intermediate portion of the wiring sidewall 34 toward the top insulation film 22 side.

The wiring recessed portion a first vertical width W1 (T1<W1) exceeding the first thickness T1 of the wiring barrier film 30 with respect to the laminated direction. The first vertical width W1 may be not less than 0.01 μm and not more than 1 μm. Preferably, the first vertical width W1 is equal to or less than 0.5 μm. The wiring recessed portion 37 has a first horizontal width W2 (T1<W2) exceeding the first thickness T1 with respect to a direction (first and second directions X and Y) perpendicular to the laminated direction. The first horizontal width W2 may be not less than 0.01 μm and not more than 1 μm. Preferably, the first horizontal width W2 is equal to or less than 0.5 μm.

The wiring electrode 31 has a wiring upper end corner portion 38 formed in a round shape. The wiring upper end corner portion 38 is a corner portion that connects the wiring upper surface 33 and the wiring sidewall 34 (wiring upper end portion 35). In other words, the wiring upper end corner portion 38 connects the wiring upper surface 33 and the wiring sidewall 34 in a circular arc shape (curved shape). That is, the wiring upper end corner portion 38 is diagonally downwardly inclined in a circular arc shape from the wiring upper surface 33 toward the wiring sidewall 34 in a peripheral edge portion of the wiring upper surface 33.

The center of curvature of the circular arc is placed at either one of the inside of the wiring electrode 31 and the inside of the interlayer insulation film 21 (top insulation film 22). In this embodiment, the wiring upper end corner portion 38 includes a portion that faces the wiring barrier film 30 in the laminated direction and a portion that does not face the wiring barrier film 30. The width of the portion, which does not face the wiring barrier film 30, of the wiring upper end corner portion 38 is less than the width of the portion, which faces the wiring barrier film 30, of the wiring upper end corner portion 38 in a cross-sectional view.

The wiring upper end corner portion 38 has a round starting point portion P1 and a round ending point portion P2. The round starting point portion P1 is placed on the wiring upper surface 33 side. The round ending point portion P2 is placed on the wiring sidewall 34 side. As a matter of course, the round starting point portion P1 may be defined as being placed on the wiring sidewall 34 side, and the round ending point portion P2 may be defined as being placed on the wiring upper surface 33 side. The wiring upper end corner portion 38 has a round width WR with respect to the direction perpendicular to the laminated direction. The round width WR is a distance between the round starting point portion P1 and the round ending point portion P2 in the direction perpendicular to the laminated direction.

Preferably, the round width WR exceeds the first horizontal width W2 of the wiring recessed portion 37 (W2<WR). Also, preferably, the round width WR exceeds the first vertical width W1 of the wiring recessed portion 37 (W1<WR). Preferably, the round width WR is less than the second thickness T2 of the wiring electrode 31 (WR<T2). The round width WR may be not less than 1 μm and not more than 20 μm.

A first phantom line L1 and a second phantom line L2 are set near the wiring upper end corner portion 38 in a cross section of FIG. 6A. The first phantom line L1 is a phantom line extending along the wiring upper surface 33. The second phantom line L2 is a phantom line that connects the round starting point portion P1 and the round ending point portion P2.

When the first phantom line L1 and the second phantom line L2 are set, the wiring upper end corner portion 38 is preferably formed so that an angle θ between the first phantom line L1 and the second phantom line L2 falls within a range of more than 0° and not more than 45°. In this embodiment, the wiring upper end corner portion 38 is formed so that the angle θ falls within a range of not less than 10° and not more than 30°.

Referring to FIG. 5 and FIG. 6A, the top wiring 25 includes a wiring cover electrode 41 covering the wiring electrode 31. The wiring cover electrode 41 includes a conductor differing from the wiring electrode 31, and covers the whole area of the wiring electrode 31 as a film.

The wiring cover 41 has a third thickness T3 (T3<T2) less than the second thickness T2 of the wiring electrode 31 with respect to the laminated direction. The third thickness T3 may be not less than 0.55 μm and not more than 11 μm. Preferably, the third thickness T3 is not less than 1.1 μm and not more than 2.5 μm. Preferably, the third thickness T3 has a thickness less than the thickness of a part of the fillers included in the molding resin 7.

The wiring cover electrode 41 has a first lower surface 42, a first upper surface 43, and a first peripheral wall 44 that connects the first lower surface 42 and the first upper surface 43. The first lower surface 42 extends along the wiring upper surface 33, and the first upper surface 43 extends along the wiring upper surface 33. The first peripheral wall 44 is a sidewall of the wiring cover electrode 41, and substantially vertically extends along the laminated direction. The term “substantially vertically” also includes a form in which it extends in the laminated direction while curving (meandering).

The wiring cover electrode 41 includes a round portion 45 that covers the wiring upper end corner portion 38 as a film so as to curve along the wiring upper end corner portion 38. In other words, the round portion 45 is formed as a film so that the first lower surface 42 and the first upper surface 43 curve along the wiring upper end corner portion 38. Also, the round portion 45 is formed so as to be downwardly inclined in a circular arc shape from the wiring upper surface 33 side toward the wiring sidewall 34 side. The round portion 45 covers the whole area, which is located between the round starting point portion P1 and the round ending point portion P2, of the wiring upper end corner portion 38. The round portion 45 forms the round ending point portion P2 in a connection portion with the wiring sidewall 34.

The wiring cover electrode 41 further has a first extension portion 46 that extends to a region located outside the wiring cover electrode 41 (wiring upper end corner portion 38). The first extension portion 46 forms a peripheral edge portion of the wiring cover electrode 41, and is composed of the first lower surface 42, the first upper surface 43, and the first peripheral wall 44. The first extension portion 46 is formed in a circular arc shape that extends continuously from the round portion 45, and has a portion placed closer to the top insulation film 22 side than the wiring upper surface 33.

The first extension portion 46 faces the top insulation film 22 in the laminated direction, and faces the wiring electrode 31 (wiring sidewall 34) in the direction perpendicular to the laminated direction. The first extension portion 46 has a lower end portion placed between the wiring upper surface 33 and the top insulation film 22. The lower end portion of the first extension portion 46 is formed by a connection portion between the first lower surface 42 extending in a circular arc shape and the first peripheral wall 44 extending substantially vertically, and has a pointed shape formed at an acute angle in a cross-sectional view.

The first extension portion 46 has a first extension width W3 with respect to the direction perpendicular to the laminated direction. Preferably, the first extension width W3 exceeds the first vertical width W1 of the wiring recessed portion 37 (W1<W3). Also, preferably, the first extension width W3 exceeds the first horizontal width W2 of the wiring recessed portion 37 (W2<W3). Preferably, the first extension width W3 is less than the round width WR (W3<WR). Preferably, the first extension width W3 is equal to or less than the third thickness T3 of the wiring cover electrode 41 (W3≤ T3). As a matter of course, the first extension width W3 may exceed the third thickness T3 of the wiring cover electrode 41 (T3<W3).

In this embodiment, the wiring cover electrode 41 has a laminated structure in which a plurality of metal films are laminated. The wiring cover electrode 41 includes a first metal film 47 and a second metal film 48 that are laminated in that order from the wiring electrode 31 side. The first metal film 47 covers the whole area of the wiring upper surface 33 as a film, and forms the first lower surface 42 of the wiring cover electrode 41 and a part of the first peripheral wall 44.

The first metal film 47 includes a high-hardness metal film higher in hardness than the wiring electrode 31. Preferably, the first metal film 47 includes an Ni-based metal film. In this embodiment, the first metal film 47 includes a pure Ni film (Ni film whose purity is equal to or more than 99%). The first metal film 47 has a fourth thickness T4. The fourth thickness T4 may be not less than 0.5 μm and not more than 6 μm.

The second metal film 48 covers the whole area of the second metal film 48 as a film, and forms the first upper surface 43 of the wiring cover electrode 41 and a part of the first peripheral wall 44. Preferably, the second metal film 48 includes a Pd-based metal film. In this embodiment, the second metal film 48 includes a pure Pd film (Pd film whose purity is equal to or more than 99%).

The second metal film 48 has a fifth thickness T5 (T5<T4) less than the fourth thickness T4 of the first metal film 47. The fifth thickness T5 may be not less than 0.05 μm and not more than 1 μm. Preferably, the fifth thickness T5 is not less than 0.1 μm and not more than 0.5 μm. A total value of the fourth thickness T4 and the fifth thickness T5 is the third thickness T3.

Referring to FIG. 4 and FIG. 5, the electronic component 1A includes a plurality of via electrodes 50 arranged inside the insulation layer 20. The via electrodes 50 include a plurality of first via electrodes 51 arranged in the interlayer insulation film 21 and a plurality of second via electrodes 52 arranged inside the top insulation film 22. The first via electrodes 51 pass through corresponding interlayer insulation films 21 so as to electrically connect arbitrary interlayer wirings 23 facing each other in the laminated direction. The second via electrodes 52 each pass through the top insulation film 22 and the uppermost interlayer insulation film 21 so as to electrically connect an arbitrary interlayer wiring 23 and an arbitrary top wiring 25 facing each other in the laminated direction.

The via electrodes 50 are each embedded in a via hole 53 formed in the insulation layer 20. The via electrodes 50 each have a laminated structure including a via barrier film 54 and a via body 55. The via barrier film 54 covers an inner wall of the via hole 53 as a film. The via barrier film 54 may include a Ti-based metal film. The via body 55 is embedded in the via hole 53 with the via barrier film 54 between the via body 55 and the via hole 53. The via body 55 may include tungsten.

Referring to FIG. 4 to FIG. 6A, the electronic component 1A includes an underlay resin film 60 (organic film) formed on the insulation layer 20. In other words, the underlay resin film 60 is interposed between the conductive plate 8 and the multilayer wiring structure 24. The underlay resin film 60 has an elastic modulus lower than the elastic modulus of the top insulation film 22, and is comparatively soft.

The underlay resin film 60 is made of a resin material differing from the molding resin 7 mentioned above. In detail, the underlay resin film 60 includes a photosensitive resin (i.e., transparent resin). The underlay resin film 60 may include at least one among an epoxy resin film, a polyimide resin film, a polyamide resin film, a polybenzoxazole resin film, and a phenol resin film. In this embodiment, the underlay resin film 60 has a single layer structure consisting of a phenol resin film.

The underlay resin film 60 is formed at a distance inwardly from the peripheral edge (first to fourth side surfaces 16A to 16D) of the insulation layer 20 in a plan view, and exposes the peripheral edge portion of the insulation layer 20. The underlay resin film 60 covers the wiring sidewall 34 of the wiring electrode 31 in a region between the top wirings 25 on the insulation layer 20. The underlay resin film 60 fills the wiring recessed portion 37 in the wiring lower end portion 36 of the wiring sidewall 34.

In the wiring recessed portion 37, the underlay resin film 60 comes into contact with the top insulation film 22, with the wiring barrier film 30, and with the wiring electrode 31. The underlay resin film 60 fills a gap between the wiring sidewall 34 and the first extension portion 46 of the wiring cover electrode 41 in the wiring upper end portion 35 of the wiring sidewall 34. In other words, the underlay resin film 60 comes into contact with the wiring sidewall 34 of the wiring electrode 31 and with the first lower surface 42 of the wiring cover electrode 41 on the wiring upper end portion 35 side.

The underlay resin film 60 includes an overlap portion 61 covering the first upper surface 43 of the wiring cover electrode 41. The overlap portion 61 extends from the first peripheral wall 44 toward the inward side of the first upper surface 43. The overlap portion 61 divisionally forms a pad opening 62 that partially exposes the wiring cover electrode 41 in an inward portion of the wiring cover electrode 41. The overlap portion 61 covers the wiring upper end corner portion 38 of the wiring electrode 31 with the wiring cover electrode 41 between the overlap portion 61 and the wiring upper end corner portion 38. Preferably, the overlap portion 61 covers the whole area of the round portion 45 of the wiring cover electrode 41.

Preferably, the overlap portion 61 covers the whole area of a region between the round starting point portion P1 and the round ending point portion P2 of the wiring electrode 31 across the wiring cover electrode 41. In other words, preferably, the overlap portion 61 has an overlap width WO (WR≤WO) equal to or more than the round width WR with respect to the direction perpendicular to the laminated direction. The overlap width WO may be not less than 1 μm and not more than 40 μm. The overlap width WO may exceed the second thickness T2 of the wiring electrode 31 (T2<WO), or may be equal to or less than the second thickness T2 (WO≤T2).

The overlap portion 61 has a sixth thickness T6 with respect to the laminated direction. The sixth thickness T6 may be not less than 1 μm and not more than 40 μm. The sixth thickness T6 may exceed the third thickness T3 of the wiring cover electrode 41 (T3<T6). The sixth thickness T6 may exceed the round width WR (WR<T6). The sixth thickness T6 may exceed the second thickness T2 (T2<T6), or may be equal to or less than the second thickness T2 (T6≤T2). Preferably, the sixth thickness T6 has a thickness less than the thickness of a part of the fillers included in the molding resin 7.

Referring to FIG. 4, FIG. 5, and FIG. 6B, the electronic component 1A includes a plurality of pad structures 65 that are each arranged on a corresponding one of the top wirings 25 so as to be electrically connected to a corresponding one of the top wirings 25. The pad structures 65 are terminal electrodes each of which is interposed between the conductive plate 8 and the top wiring 25 and each of which electrically connects the conductive plate 8 and the top wiring 25. A detailed structure of the single pad structure 65 will be hereinafter described.

The pad structure 65 includes a pad barrier film 70 that selectively covers the top wiring 25. In detail, the pad barrier film 70 covers the first upper surface 43 of the wiring cover electrode 41 and the overlap portion 61 of the underlay resin film 60 as a film. A portion, which covers the overlap portion 61, of the pad barrier film 70 is placed at a higher position than a portion, which covers the first upper surface 43, of the pad barrier film 70.

The pad barrier film 70 is made of a high-hardness metal film having a comparatively small thermal expansion coefficient. The pad barrier film 70 includes at least one among a Ti film, a TiN film, a Ta film, a W film, a Mo film, a Cr film, and a Ru film. The thermal expansion coefficient of the pad barrier film 70 may be not less than 4 μm/m·K and not more than 9 μm/m·K. Preferably, the pad barrier film 70 includes a Ti-based metal.

The pad barrier film 70 may have a laminated structure or a single layer structure including at least either one of a Ti film and a TiN film. The pad barrier film 70 may have a laminated structure including a Ti film and a TiN film that are laminated in that order from the top wiring 25 side. In this embodiment, the pad barrier film 70 has a single layer structure consisting of a Ti film.

The pad barrier film 70 has a seventh thickness T7 with respect to the laminated direction. The seventh thickness T7 may be not less than 0.01 μm and not more than 0.5 μm. Preferably, the seventh thickness T7 is not less than 0.05 μm and not more than 0.2 μm. The pad barrier film 70 may have the same material and/or the same thickness as the wiring barrier film 30.

The pad structure 65 includes a pad electrode 71 covering the pad barrier film 70. The pad electrode may be referred to as a “terminal electrode.” The pad electrode 71 forms a main body of the pad structure 65, and has a pillar shape erected along the laminated direction in a cross-sectional view. The pad electrode 71 includes a metal film differing from the pad barrier film 70. In detail, the pad electrode 71 includes a low-hardness metal film having a thermal expansion coefficient exceeding the thermal expansion coefficient of the pad barrier film 70.

The pad electrode 71 may include at least either one of an Al-based metal film and a Cu-based metal film. The pad electrode 71 may include at least one among a pure Al film (Al film whose purity is equal to or more than 99%), a pure Cu film (Cu film whose purity is equal to or more than 99%), an AlCu alloy film, an AlSi alloy film, and an AlSiCu alloy film. Preferably, the pad electrode 71 is made of a Cu-based metal film. In this embodiment, the pad electrode 71 is made of a pure Cu film. In this embodiment, the thermal expansion coefficient of the pad electrode 71 is about 16.5 μm/m·K.

The pad electrode 71 has an eighth thickness T8 (T7<T8) exceeding the seventh thickness T7 of the pad barrier film 70 with respect to the laminated direction. The eighth thickness T8 is the thickness of the pad electrode 71 on the basis (zero point) of the top wiring 25 (wiring cover electrode 41). The eighth thickness T8 exceeds the second thickness T2 of the wiring electrode 31 (T2<T8). Preferably, the eighth thickness T8 is less than the thickness of the conductive plate 8.

Preferably, the eighth thickness T8 exceeds the sixth thickness T6 of the underlay resin film 60 (overlap portion 61) (T6<T8). The eighth thickness T8 may be not less than 10 μm and not more than 100 μm. Preferably, the eighth thickness T8 is not less than 20 μm and not more than 60 μm. Preferably, the eighth thickness T8 has a thickness exceeding the thickness of the fillers included in the molding resin 7.

The pad electrode 71 covers the overlap portion 61 of the underlay resin film 60 at a distance inwardly from the wiring upper end corner portion 38 of the wiring electrode 31 in a plan view. In other words, the pad electrode 71 is formed at a distance inwardly from the round portion 45 of the wiring cover electrode 41, and does not face the round portion 45 across the underlay resin film 60 (overlap portion 61).

The pad electrode 71 enters the pad opening 62 from above the underlay resin film 60 (overlap portion 61), and is connected to the wiring cover electrode 41 via the pad barrier film 70 in the pad opening 62. The pad electrode 71 covers the whole area of the pad barrier film 70 in a cross-sectional view and in a plan view. In this embodiment, the pad electrode 71 has a peripheral edge portion that projects to a region located outside the pad barrier film 70 and that faces the underlay resin film 60 in the laminated direction.

The pad electrode 71 includes a pad lower surface 72, a pad upper surface 73, and a pad sidewall 74. The pad lower surface 72 extends along the first upper surface 43 of the wiring cover electrode 41 and along the overlap portion 61 of the underlay resin film 60. A portion, which covers the overlap portion 61, of the pad lower surface 72 is placed at a higher a portion, which covers the first upper surface 43, of the pad lower surface 72. The pad upper surface 73 extends along the first upper surface 43 of the wiring cover electrode 41 and along the overlap portion 61 of the underlay resin film 60.

A portion, which covers the first upper surface 43, of the pad upper surface 73 is hollowed toward the wiring cover electrode 41. In other words, a portion, which covers the overlap portion 61, of the pad upper surface 73 is placed at a higher position than the portion, which covers the first upper surface 43, of the pad upper surface 73. The pad sidewall 74 is placed on the underlay resin film 60, and substantially vertically extends along the normal direction Z. The term “substantially vertically” also includes a form in which it extends in the laminated direction while curving (meandering). The pad sidewall 74 is placed in a region located outside the pad barrier film 70, and faces the underlay resin film 60 in the laminated direction without the pad barrier film 70 between the pad sidewall 74 and the underlay resin film 60.

The pad sidewall 74 has a pad upper end portion 75 on the pad upper surface 73 side and a pad lower end portion 76 on the base resin film 60 side. The pad sidewall 74 has a pad recessed portion 77 that is hollowed inward than the pad upper end portion 75 in the pad lower end portion 76. The pad recessed portion 77 forms an uneven portion (pad uneven portion) in the pad lower end portion 76. The pad recessed portion 77 may be hollowed inward than the pad upper end portion 75. The pad recessed portion 77 may be hollowed in a curved shape.

The pad recessed portion 77 exposes a peripheral edge portion of the pad barrier film 70. In detail, the pad recessed portion 77 has an upper end portion placed outward from the peripheral edge of the pad barrier film 70 and a lower end portion placed inward from the peripheral edge of the pad barrier film 70. In this embodiment, the pad recessed portion 77 also exposes the underlay resin film 60. The pad recessed portion 77 is formed at a distance from an intermediate portion of the pad sidewall 74 toward the top wiring 25 side.

The pad recessed portion 77 has a second vertical width W4 (T7<W4) exceeding the seventh thickness T7 of the pad barrier film 70 with respect to the laminated direction. The second vertical width W4 may be not less than 0.01 μm and not more than 1 μm. Preferably, the second vertical width W4 is equal to or less than 0.5 μm. The pad recessed portion 77 has a second horizontal width W5 (T7<W5) exceeding the seventh thickness T7 of the pad barrier film 70 with respect to the direction perpendicular to the laminated direction. The second horizontal width W5 may be not less than 0.01 μm and not more than 1 μm. Preferably, the second horizontal width W5 is equal to or less than 0.5 μm.

The pad electrode 71 has an angular pad upper end corner portion 78, unlike the wiring upper end corner portion 38 of the wiring electrode 31. The pad upper end corner portion 78 is a corner portion connecting the pad upper surface 73 and the pad sidewall 74 (pad upper end portion 75). Where the hollow of the pad upper surface 73 reaches the pad sidewall 74, the pad upper end corner portion 78 may have a pointed shape that upwardly protrudes at an acute angle because of that hollow in a cross-sectional view. In this embodiment, the wiring upper end corner portion 38 faces the underlay resin film 60 without the pad barrier film 70 between the wiring upper end corner portion 38 and the underlay resin film 60 in the laminated direction.

The pad electrode 71 includes a pad cover electrode 81 covering the pad electrode 71. The pad cover electrode 81 includes a conductor differing from the pad electrode 71, and covers the whole area of the pad electrode 71 as a film.

The pad cover electrode 81 has a ninth thickness T9 (T9<T8) less than the eighth thickness T8 of the pad electrode 71 with respect to the laminated direction. The ninth thickness T9 may be not less than 0.5 μm and not more than 6 μm. Preferably, the ninth thickness T9 is not less than 1 μm and not more than 5 μm. Preferably, the ninth thickness T9 has a thickness less than the thickness of a part of the fillers included in the molding resin 7.

The pad cover electrode 81 has a second lower surface 82, a second upper surface 83, and a second peripheral wall 84 connecting the second lower surface 82 and the second upper surface 83. The second lower surface 82 extends along the pad upper surface 73, and the second upper surface 83 extends along the pad upper surface 73. The second peripheral wall 84 is a sidewall of the pad cover electrode 81, and substantially vertically extends along the laminated direction. The term “substantially vertically” also includes a form in which it extends in the laminated direction while curving (meandering).

The pad cover electrode 81 has a second extension portion 86 that extends to a region located outside the pad cover electrode 81 (pad upper end corner portion 78). The second extension portion 86 forms a peripheral edge portion of the pad cover electrode 81, and is composed of the second lower surface 82, the second upper surface 83, and the second peripheral wall 84. The second extension portion 86 faces the top wiring 25 in the laminated direction. An angle between the second lower surface 82 and the second peripheral wall 84 of the pad cover electrode 81 exceeds an angle between the first lower surface 42 and the first peripheral wall 44 of the wiring cover electrode 41.

The second extension portion 86 has a second extension width W6 with respect to the direction perpendicular to the laminated direction. Preferably, the second extension width W6 exceeds the second vertical width W4 of the pad recessed portion 77 (W4<W6). Also, preferably, the second extension width W6 exceeds the second horizontal width W5 of the pad recessed portion 77 (W5<W6). Preferably, the second extension width W6 is equal to or less than the ninth thickness T9 of the pad cover electrode 81 (W6≤T9). As a matter of course, the second extension width W6 may exceed the ninth thickness T9 of the pad cover electrode 81 (T9<W6).

In this embodiment, the pad cover electrode 81 has a single layer structure consisting of a single third metal film 87 unlike the wiring cover electrode 41. The third metal film 87 covers the whole area of the pad upper surface 73 as a film, and forms the second lower surface 82, the second upper surface 83, and the second peripheral wall 84 of the wiring cover electrode 41. The third metal film 87 includes a high-hardness metal film higher in hardness than the pad electrode 71. Preferably, the third metal film 87 includes an Ni-based metal film. In this embodiment, the third metal film 87 includes a pure Ni film (Ni film whose purity is equal to or more than 99%).

The pad structure 65 further includes a plurality of low-melting metals 90 that are each arranged on a corresponding one of the pad electrodes 71 so as to be electrically connected to the corresponding pad electrode 71. The low-melting metal 90 is interposed between the conductive plate 8 and the pad electrode 71, and mechanically and electrically connects the conductive plate 8 and the pad electrode 71. In this embodiment, the low-melting metal 90 is solder. Preferably, the low-melting metal 90 is lead-free solder. In this embodiment, the low-melting metal 90 is made of solder including at least either one of Sn and Ag. A structure of the single low-melting metal 90 will be hereinafter described.

The low-melting metal 90 is arranged on the pad upper surface 73 so as to expose the pad sidewall 74 of the pad electrode 71. The low-melting metal 90 fills the hollow of the pad upper surface 73 on the pad cover electrode 81. In this embodiment, the low-melting metal 90 covers the whole area of the pad upper surface 73. The low-melting metal 90 covers the second extension portion 86 of the pad cover electrode 81 so as to expose the second peripheral wall 84 of the pad cover electrode 81.

The low-melting metal 90 may partially cover the second peripheral wall 84 so as to expose a part of the second peripheral wall 84. In this embodiment, the low-melting metal 90 faces the underlay resin film 60 across the second extension portion 86. The low-melting metal 90 has a bulge portion 91 that projects to a region located outside the second extension portion 86. The bulge portion 91 projects in a circular arc shape while setting the second extension portion 86 as a starting point. The bulge portion 91 faces the underlay resin film 60 without the second extension portion 86 between the bulge portion 91 and the underlay resin film 60.

The low-melting metal 90 has a tenth thickness T10 (T9<T10) exceeding the ninth thickness T9 in the laminated direction. The tenth thickness T10 is the greatest thickness of the low-melting metal 90. Preferably, the tenth thickness T10 exceeds the second thickness T2 of the wiring electrode 31 (T2<T10). The tenth thickness T10 may be equal to or less than the eighth thickness T8 of the pad electrode 71 (T10≤ T8), or may exceed the eighth thickness T8 (T8<T10). Preferably, the tenth thickness T10 is less than the thickness of the conductive plate 8. Preferably, the tenth thickness T10 has a thickness less than the thickness of a part of the fillers included in the molding resin 7.

Referring to FIG. 4, FIG. 5, and FIG. 6B, the electronic component 1A includes an overlay resin 95 that covers the underlay resin film 60. The overlay resin 95 is made of a resin material differing from the underlay resin film 60. The overlay resin 95 has an elastic modulus higher than the elastic modulus of the underlay resin film 60, and is higher in hardness than the underlay resin film 60. In this embodiment, the overlay resin 95 is made of a part of the molding resin 7 mentioned above.

The overlay resin 95 is interposed between the conductive plate 8 and the underlay resin film 60, and covers the conductive plate 8, the underlay resin film 60, the pad electrodes 71, and the low-melting metals 90. Also, the overlay resin 95 covers the peripheral edge portion, which is exposed from the underlay resin film 60, of the insulation layer 20.

The overlay resin 95 covers the pad sidewall 74 of the pad electrode 71 in a region between the pad electrodes 71 on the underlay resin film 60. The overlay resin 95 has a portion that covers the top insulation film 22 across the underlay resin film 60. The overlay resin 95 has a portion that covers the wiring upper end corner portion 38 of the wiring electrode 31 across the underlay resin film 60. The overlay resin 95 fills the pad recessed portion 77 in the pad lower end portion 76 of the pad sidewall 74.

The overlay resin 95 comes into contact with the underlay resin film 60, with the pad barrier film 70, and with the pad electrode 71 in the pad recessed portion 77. The overlay resin 95 comes into contact with the pad sidewall 74 and the second extension portion 86 of the pad cover electrode 81 (second lower surface 82) in the pad upper end portion 75 of the pad sidewall 74. The overlay resin 95 covers the second peripheral wall 84 of the pad electrode 71 and the low-melting metal 90, and does not cover the second upper surface 83 of the pad electrode 71.

As thus described, the electronic component 1A includes the semiconductor chip 13, the multilayer wiring structure 24 (insulation layer 20), the pad structure 65 (pad electrodes 71), and the low-melting metals 90. In the package 2A, the electronic component 1A is arranged in the package body 3 in an orientation in which the pad structure 65 is allowed to face the conductive plate 8. The pad electrodes 71 are joined to a correspondence place (die pad portion 9 or lead portion 10) of the conductive plate 8 via a corresponding one of the low-melting metals 90. Hence, an electric signal from the conductive plate 8 is given to the electronic component 1A, and an electric signal from the electronic component 1A is given to the conductive plate 8.

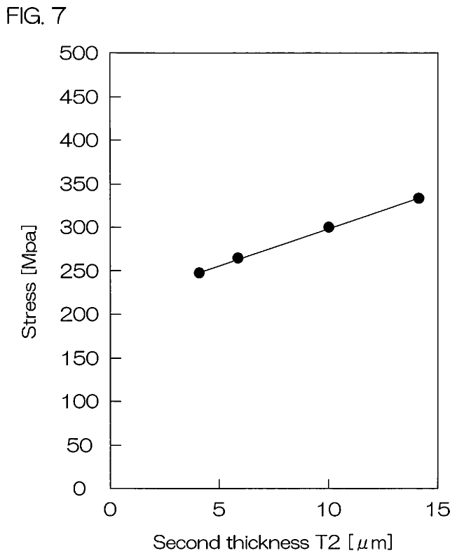

Referring to FIG. 7 to FIG. 10, stress generated in the underlay resin film 60 near the wiring upper end corner portion 38 will be hereinafter described. In detail, the stress generated in the underlay resin film 60 is stress applied from the first extension portion 46 to the underlay resin film 60 (hereinafter, the same applies). FIG. 7 is a graph showing a relationship between the second thickness T2 of the wiring electrode 31 and stress. In FIG. 7, the ordinate axis represents stress [Mpa], and the abscissa axis represents the second thickness T2 [μm]. Stress generated when the second thickness T2 is changed from 4 μm to 14 μm is shown in the graph of FIG. 7.

Referring to FIG. 7, the stress varies depending on the second thickness T2. In detail, the stress becomes higher in proportion to an increase in the second thickness T2. Therefore, in the second thickness T2, a smaller thickness is desirable. However, a resistance value will increase when the second thickness T2 is reduced. Therefore, preferably, the second thickness T2 is not less than 6 μm and not more than 12 μm. Particularly preferably, the second thickness T2 is equal to or less than 10 μm. In this case, it is possible to suppress the stress resulting from the second thickness T2 so as to be 300 Mpa or less while suppressing an increase in the resistance value.

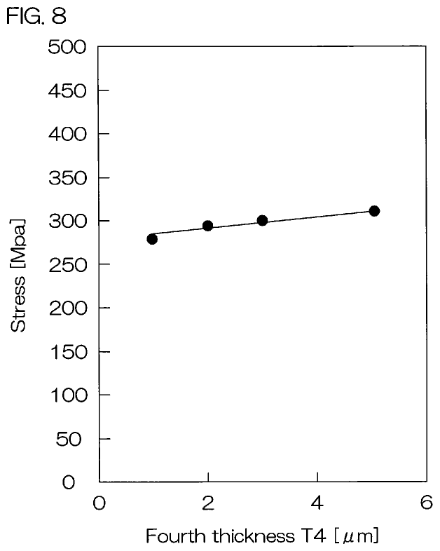

FIG. 8 is a graph showing a relationship between the fourth thickness T4 of the first metal film 47 and stress. In FIG. 8, the ordinate axis represents stress [Mpa], and the abscissa axis represents the fourth thickness T4 [μm]. Stress generated when the fourth thickness T4 is changed from 1 μm to 5 μm is shown in the graph of FIG. 8.

Referring to FIG. 8, the stress varies depending on the fourth thickness T4. In detail, the stress becomes higher in proportion to an increase in the fourth thickness T4. Therefore, in the fourth thickness T4, a smaller thickness is desirable. However, film-forming properties of the first metal film 47 (particularly, the first extension portion 46) with respect to the wiring electrode 31 will decrease when the fourth thickness T4 is reduced. Therefore, preferably, the fourth thickness T4 is not less than 1 μm and not more than 3 μm. In this case, it is possible to suppress the stress resulting from the fourth thickness T4 so as to be 300 Mpa or less while suppressing a decrease in the film-forming properties.

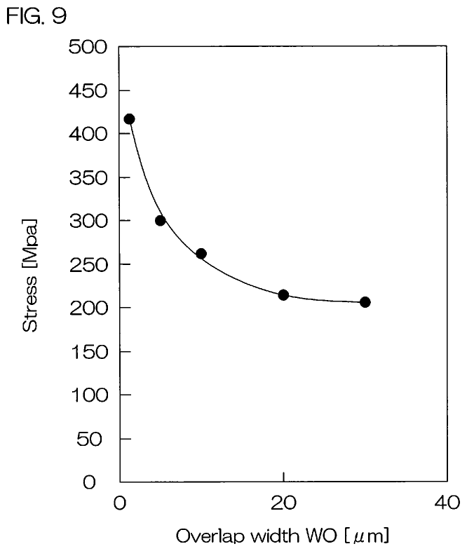

FIG. 9 is a graph showing a relationship between the overlap width WO of the underlay resin film 60 and stress. In FIG. 9, the ordinate axis represents stress [Mpa], and the abscissa axis represents the overlap width WO [μm]. Stress generated when the overlap width WO is changed from 1 μm to 30 μm is shown in the graph of FIG. 9.

Referring to FIG. 9, the stress varies depending on the overlap width WO. In detail, the stress becomes lower in proportion to an increase in the overlap width WO. Therefore, in the overlap width WO, a larger overlap width is desirable. Also, it is possible to appropriately protect the top wiring 25 by increasing the overlap width WO. Preferably, the overlap width WO is equal to or more than 5 μm. Particularly preferably, the overlap width WO is equal to or more than 10 μm.

In these cases, it is possible to suppress the stress resulting from the overlap width WO so as to be 300 Mpa or less while appropriately protecting the top wiring 25. However, the area of an exposed portion (pad opening 62) of the top wiring 25 will decrease when the overlap width WO is excessively increased. As an example, the upper limit value of the overlap width WO is equal to or less than 20 μm.

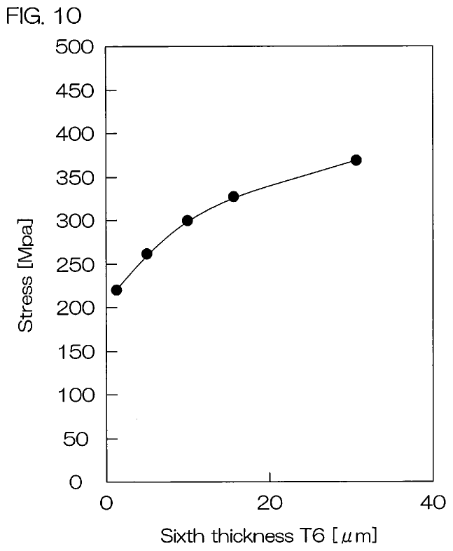

FIG. 10 is a graph showing a relationship between the sixth thickness T6 of the underlay resin film 60 and stress. In FIG. 10, the ordinate axis represents stress [Mpa], and the abscissa axis represents the sixth thickness T6 [μm]. Stress generated when the sixth thickness T6 is changed from 1 μm to 30 μm is shown in the graph of FIG. 10.

Referring to FIG. 10, the stress varies depending on the sixth thickness T6. In detail, the stress becomes higher in proportion to an increase in the sixth thickness T6. Therefore, in the sixth thickness T6, a smaller thickness is desirable. However, the protection of the top wiring 25 will become insufficient when the sixth thickness T6 is reduced. Therefore, preferably, the sixth thickness T6 is not less than 5 μm and not more than 15 μm. In this case, particularly preferably, the sixth thickness T6 is equal to or less than 10 μm. In these cases, it is possible to suppress the stress resulting from the sixth thickness T6 so as to be 300 Mpa or less while appropriately protecting the top wiring 25.

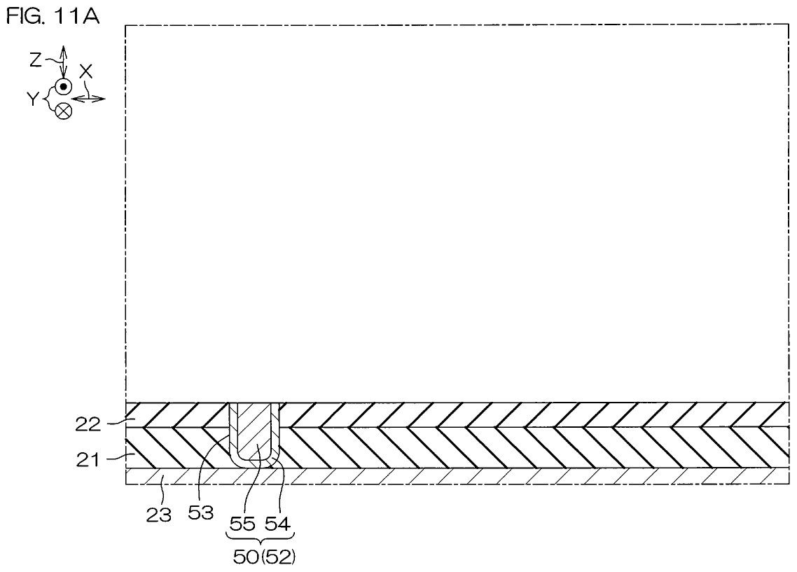

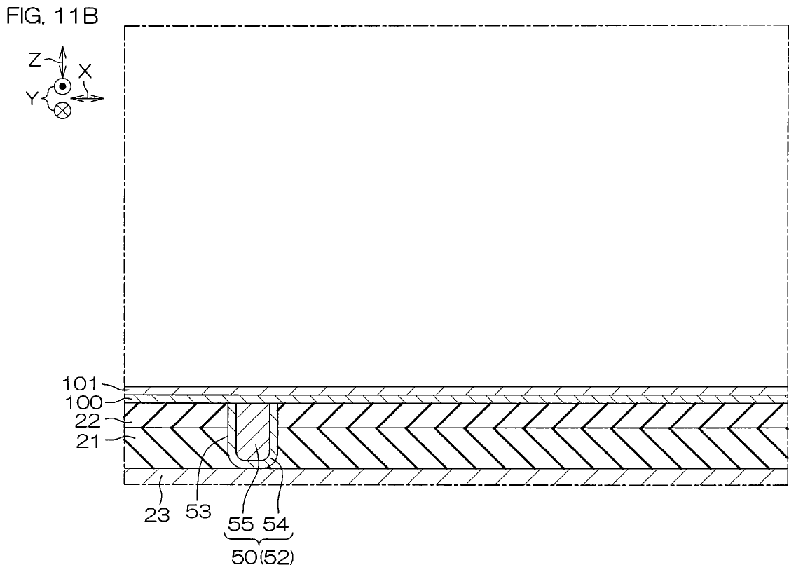

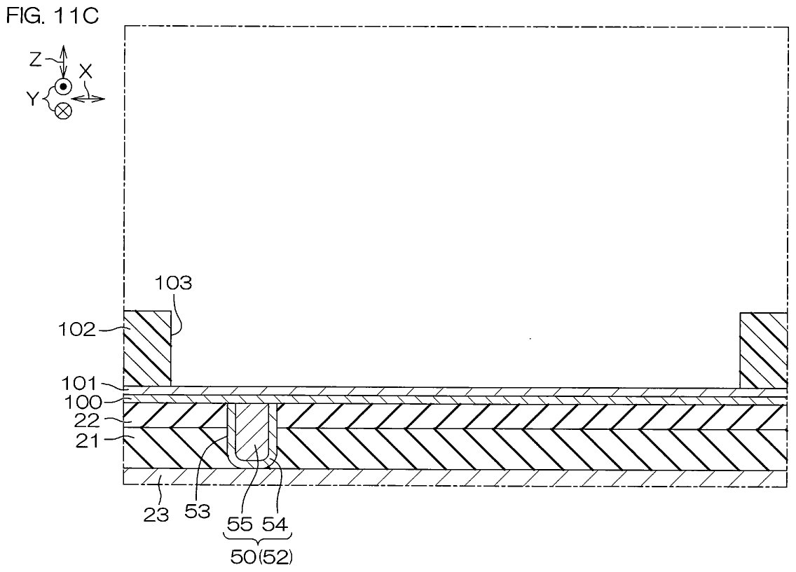

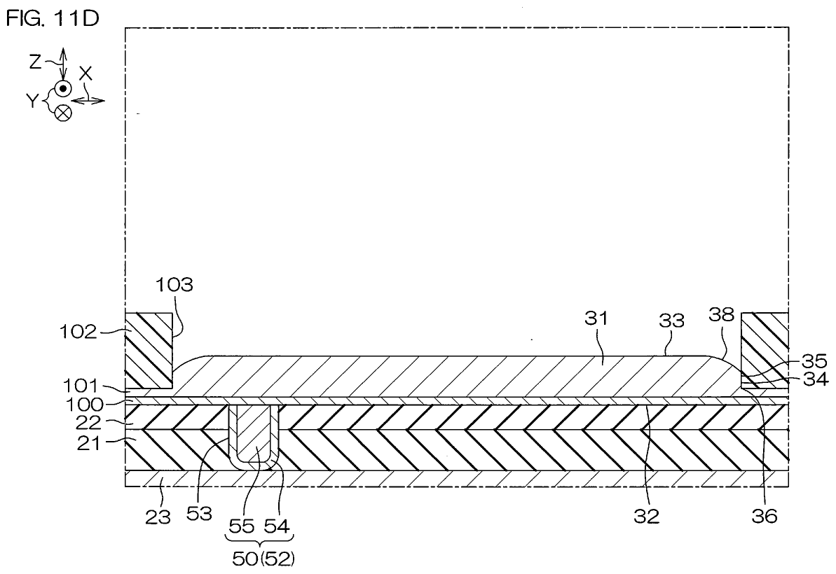

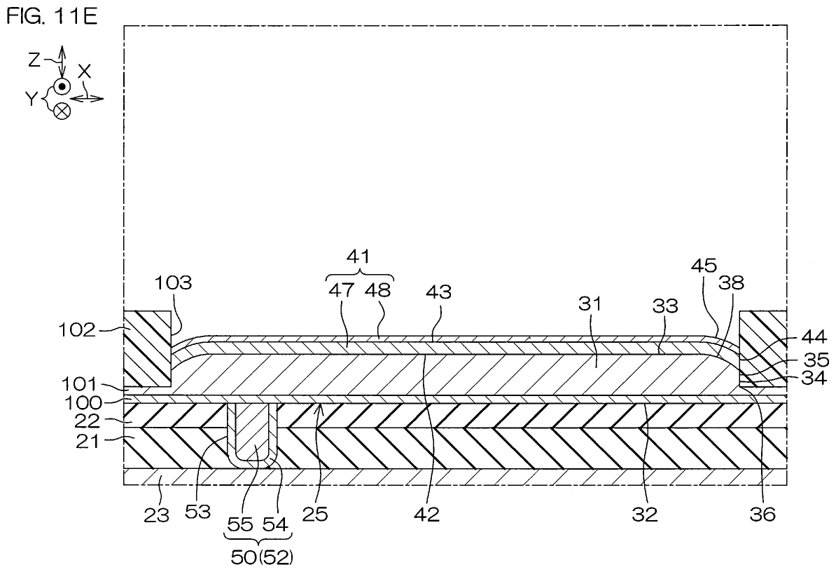

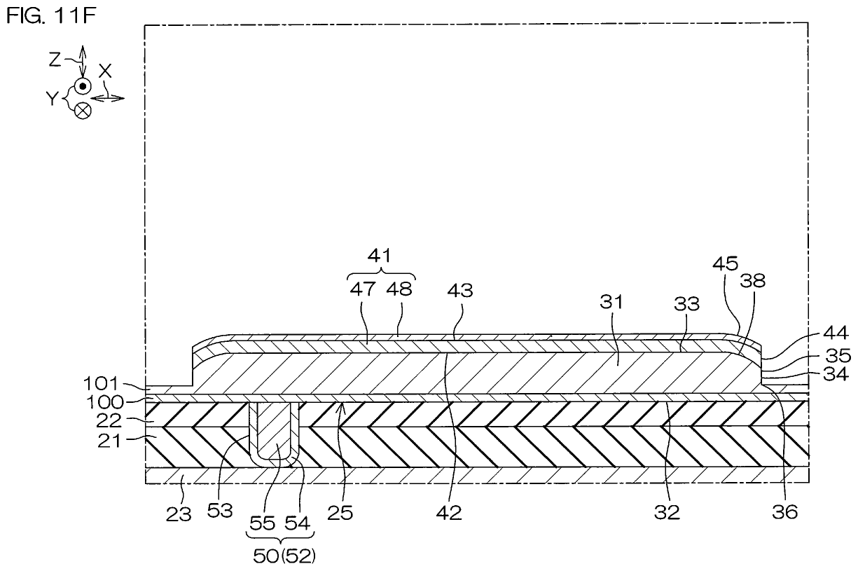

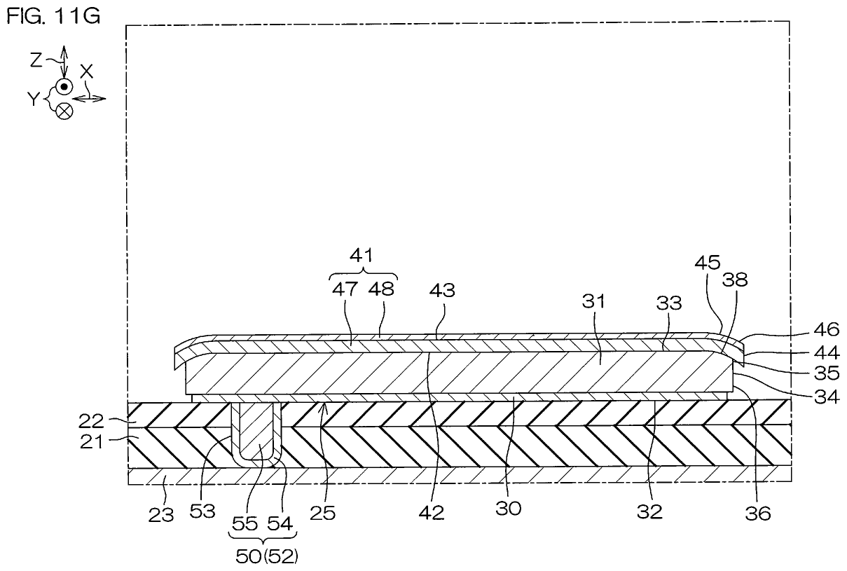

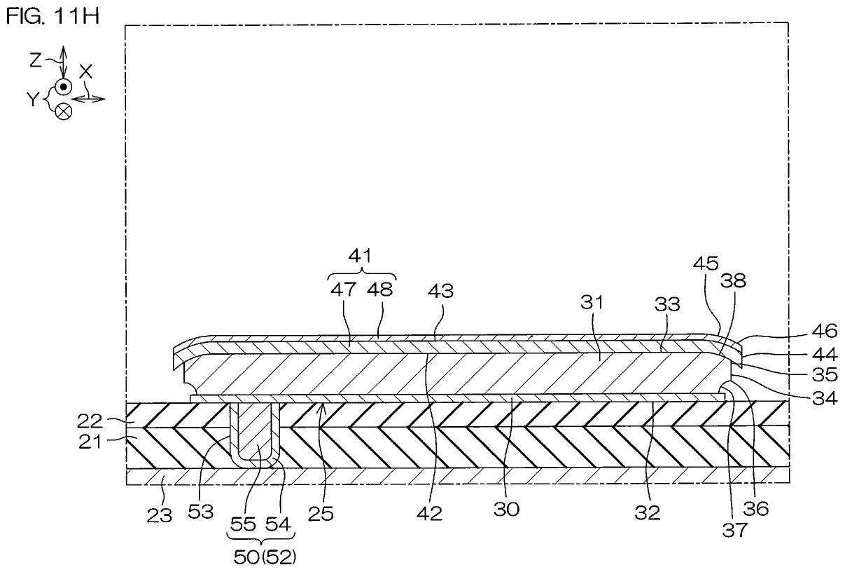

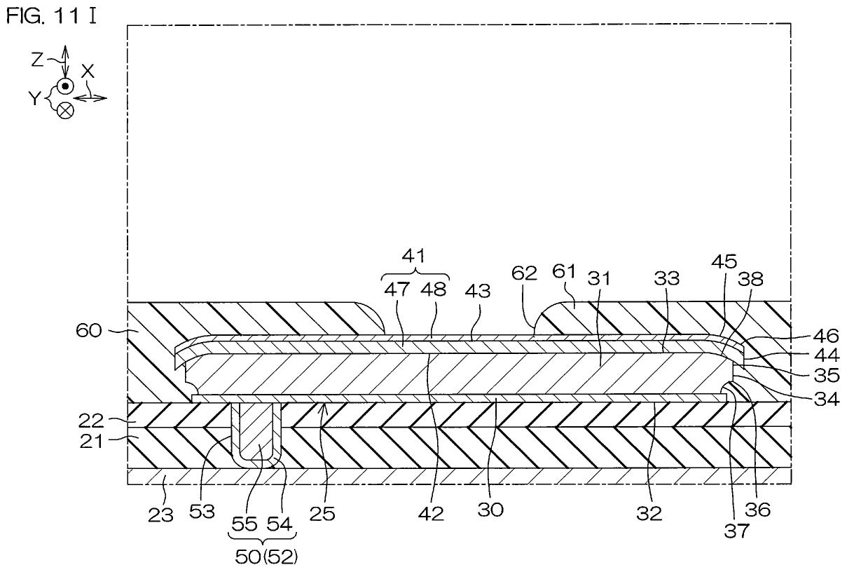

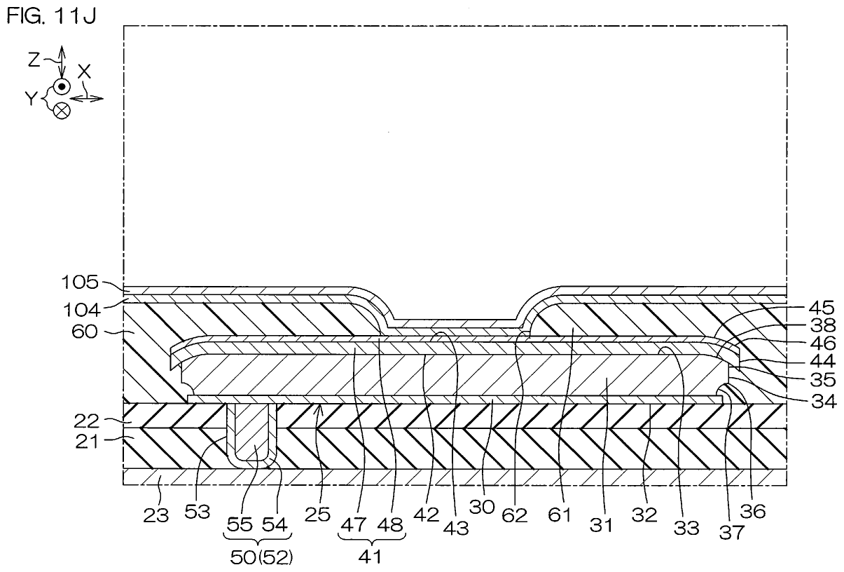

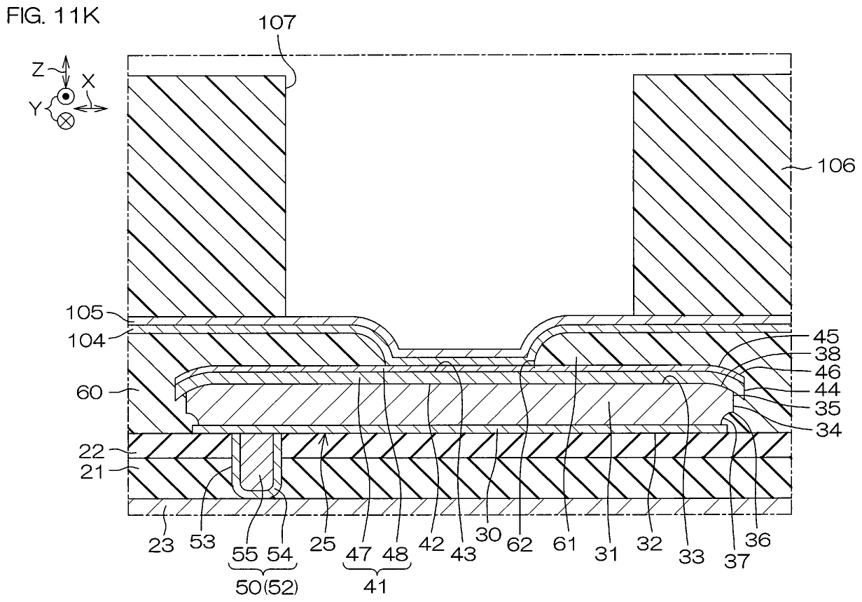

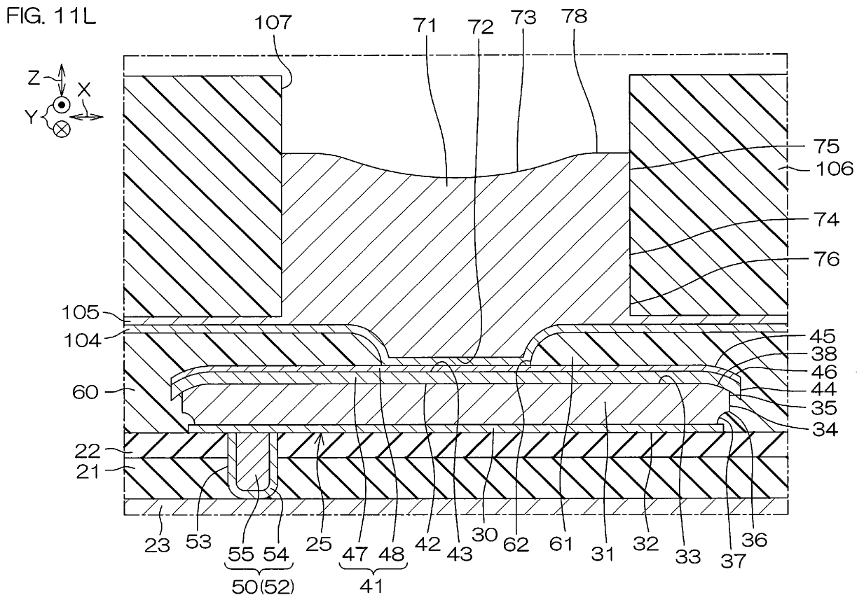

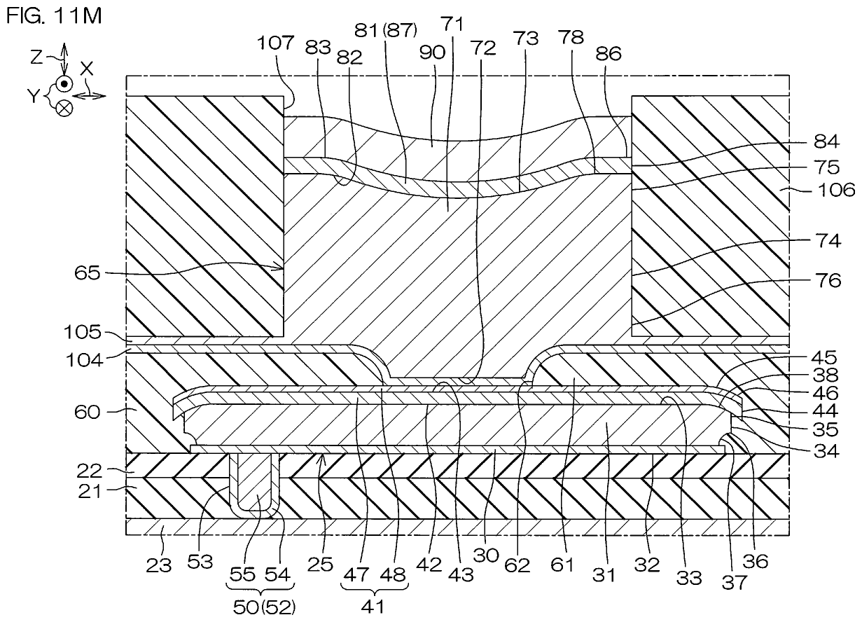

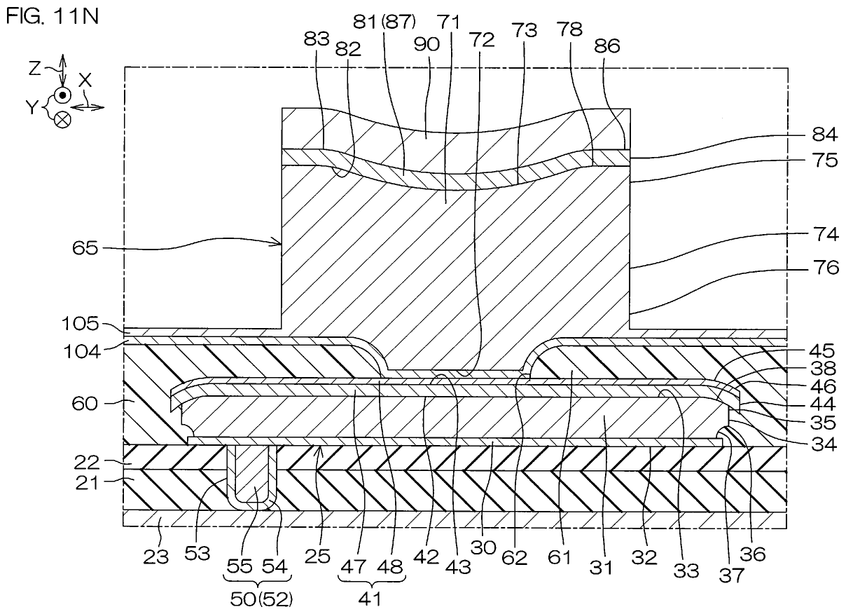

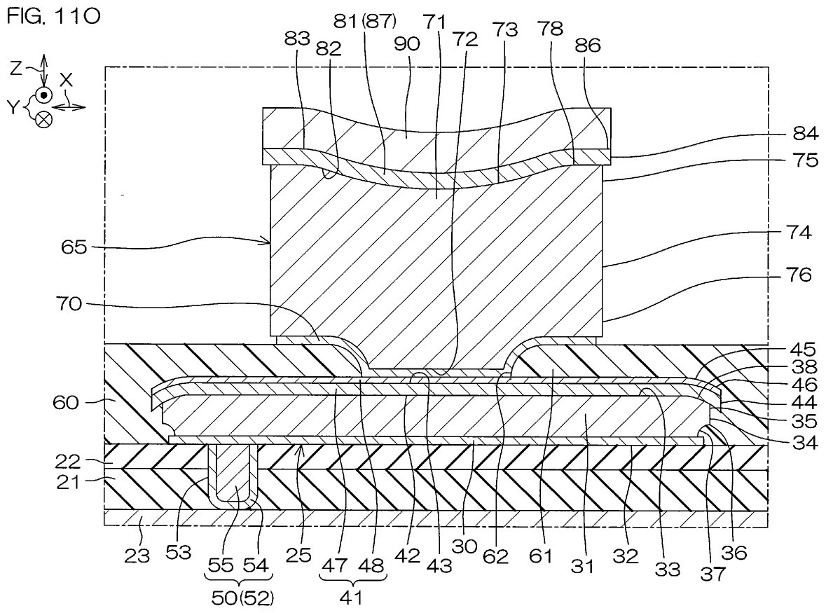

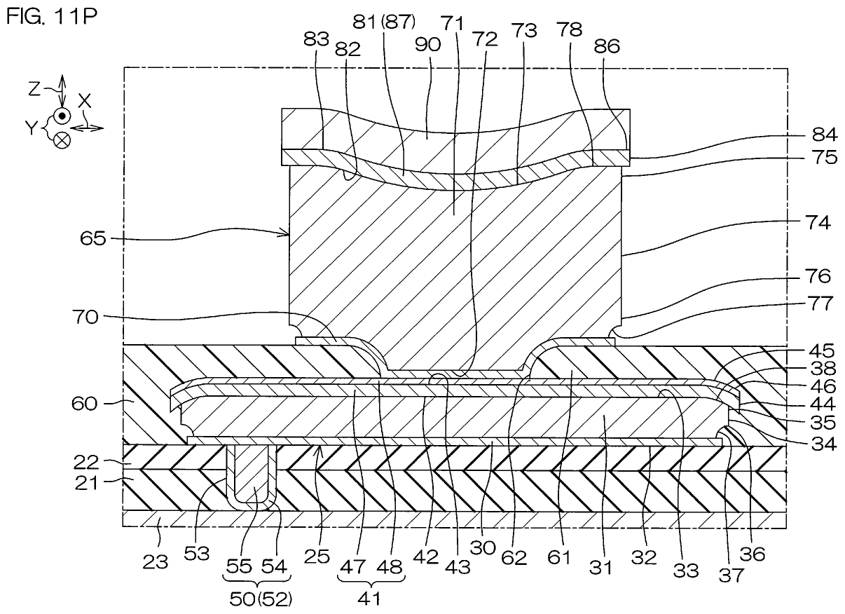

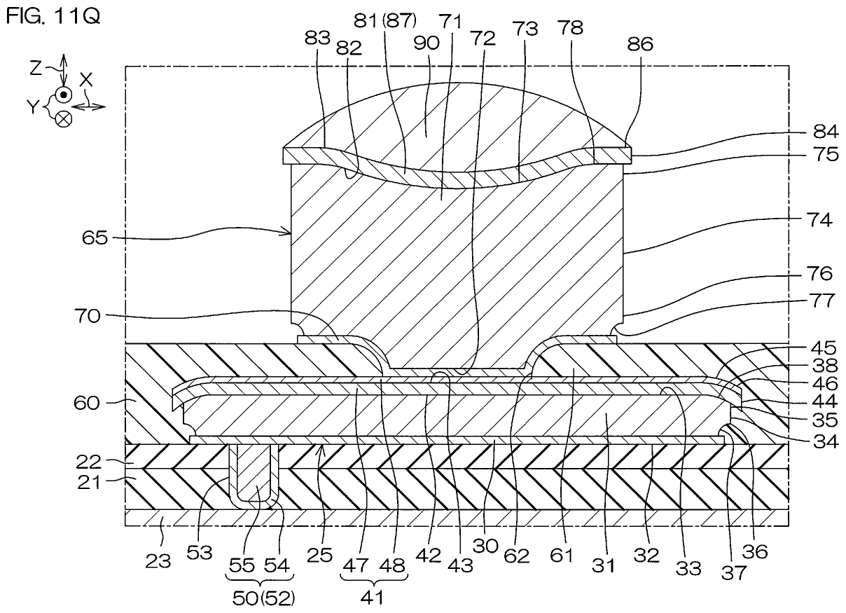

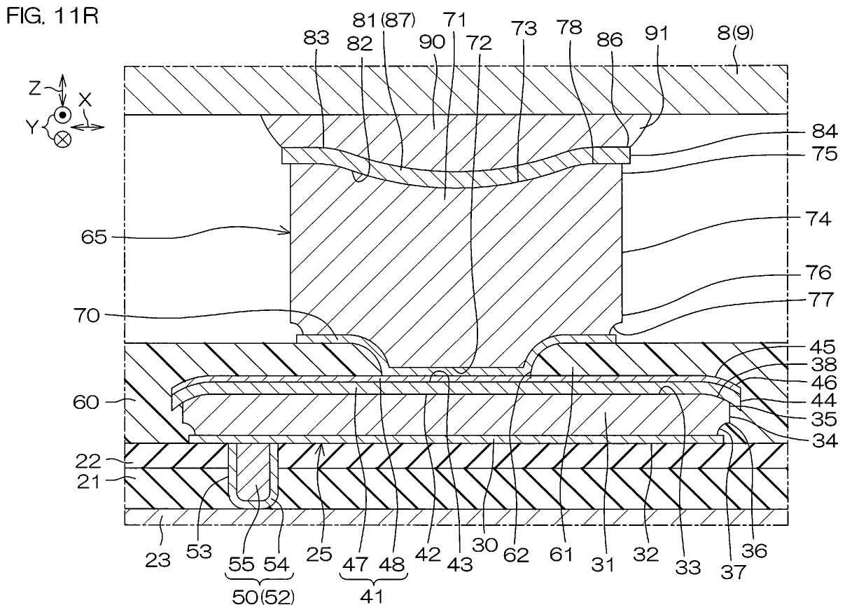

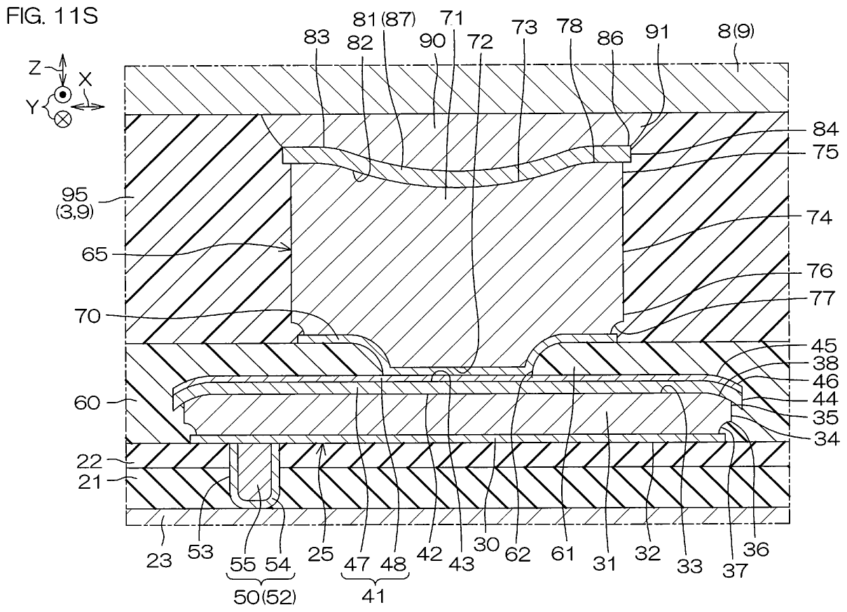

FIG. 11A to FIG. 11S are cross-sectional views each of which shows an example of a method of manufacturing the package 2A of FIG. 1. FIG. 11A to FIG. 11S are cross-sectional views of a region corresponding to FIG. 5. The method of manufacturing the package 2A includes a process of manufacturing the electronic component 1A.

Referring to FIG. 11A, a wafer (not shown) in which the multilayer wiring structure 24 is formed is prepared. The topmost surface of the multilayer wiring structure 24 is formed by the top insulation film 22 from which the second via electrodes 52 are exposed.

Next, referring to FIG. 11B, a first base barrier film 100 and a first seed film 101 are formed on the multilayer wiring structure 24. The first base barrier film 100 serves as a base of the wiring barrier film 30, and the first seed film 101 serves as a base of the wiring electrode 31. In this embodiment, the first base barrier film 100 is made of a Ti-based metal film. In this embodiment, the first seed film 101 is made of a Cu-based metal film (in detail, pure Cu film). The first base barrier film 100 and the first seed film 101 may be each formed by a sputtering method.

Next, referring to FIG. 11C, a first resist mask 102 having a predetermined pattern is formed on the first seed film 101. The first resist mask 102 has a first opening 103 that exposes a region in which the wiring electrode 31 is to be formed. Next, referring to FIG. 11D, the wiring electrode 31 is formed on the first seed film 101. The wiring electrode 31 is formed so as to be united integrally with the first seed film 101 by a plating method (for example, electrolytic plating method).

In this step, the first seed film 101 is immersed in a surfactant-free plating solution. The surfactant-free plating solution makes it possible to reduce a film-forming amount of the wiring electrode 31 near a wall surface of the first opening 103. Hence, the wiring electrode 31 having the wiring upper end corner portion 38 formed in a round shape is formed. The wiring electrode 31 is formed to a height position that is halfway in a depth direction of the first opening 103.

Next, referring to FIG. 11E, the wiring cover electrode 41 is formed on the wiring electrode 31. In this embodiment, the wiring cover electrode 41 has a laminated structure including the first metal film 47 (Ni-based metal film) and the second metal film 48 (Pd-based metal film). The first metal film 47 is formed on the wiring electrode 31 by a plating method (for example, electroless plating method). The second metal film 48 is formed on the first metal film 47 by the plating method (for example, electroless plating method). Next, referring to FIG. 11F, the first resist mask 102 is removed.

Next, referring to FIG. 11G, a portion, which is exposed from the wiring electrode 31, of the first seed film 101 is removed. The unnecessary portions of the first seed film 101 may be removed by an etching method (for example, wet etching method). In this step, the wiring sidewall 34 of the wiring electrode 31 is removed by an amount according to the thickness of the first seed film 101. Therefore, the wiring sidewall 34 recedes inward than the first peripheral wall 44 of the wiring cover electrode 41. Hence, the first extension portion 46 of the wiring cover electrode 41 is formed.

Next, a portion, which is exposed from the wiring electrode 31, of the first base barrier film 100 is removed. The unnecessary portions of the first base barrier film 100 may be removed by the etching method (for example, wet etching method). In this step, a portion, which is located directly under the wiring electrode 31, of the first base barrier film 100 is removed by an amount according to the thickness of the first base barrier film 100. Therefore, the first base barrier film 100 recedes inward than the wiring sidewall 34 of the wiring electrode 31. Hence, the wiring barrier film 30 is formed.

Next, referring to FIG. 11H, the wiring recessed portion 37 is formed at the wiring lower end portion 36 of the wiring electrode 31. The wiring recessed portion 37 is formed by partially removing the wiring lower end portion 36 of the wiring electrode 31 by the etching method (for example, wet etching method). The size and the shape of the wiring recessed portion 37 are regulated by adjusting the etching condition.

Next, referring to FIG. 11I, the underlay resin film 60 is formed on the wiring electrode 31. In this step, a photosensitive resin that serves as a base of the underlay resin film 60 is first applied onto the top insulation film 22. As a matter of course, a filmy photosensitive resin may be stuck on the top insulation film 22. Next, the photosensitive resin is exposed and developed with a pattern corresponding to the pad opening 62. Hence, the underlay resin film 60 having the pad opening 62 that exposes the wiring electrode 31 is formed.

Next, referring to FIG. 11J, a second base barrier film 104 and a second seed film 105 are formed on the wiring electrode 31 and the underlay resin film 60. The second base barrier film 104 serves as a base of the pad barrier film 70, and the second seed film 105 serves as a base of the pad electrode 71. In this embodiment, the second base barrier film 104 is made of a Ti-based metal film. In this embodiment, the second seed film 105 is made of a Cu-based metal film (in detail, pure Cu film). The second base barrier film 104 and the second seed film 105 may be each formed by the sputtering method.

Next, referring to FIG. 11K, a second resist mask 106 having a predetermined pattern is formed on the second seed film 105. The second resist mask 106 has a second opening 107 that exposes a region in which the pad electrode 71 is to be formed.

Next, referring to FIG. 11L, the pad electrode 71 is formed on the second seed film 105. The pad electrode 71 is formed so as to be united integrally with the second seed film 105 by the plating method (for example, electrolytic plating method). In this step, the second seed film 105 is immersed in a plating solution that contains surfactant. The pad electrode 71 is formed to a height position that is halfway in a thickness direction of the second resist mask 106.

Next, referring to FIG. 11M, the pad cover electrode 81 is formed on the pad electrode 71. In this embodiment, the pad cover electrode 81 has a single layer structure consisting of the third metal film 87 (Ni-based metal film). The third metal film 87 is formed on the pad electrode 71 by the plating method (for example, electroless plating method). Next, the low-melting metal 90 is formed on the pad cover electrode 81. In this embodiment, the low-melting metal 90 includes SnAg. The low-melting metal 90 is formed on the pad cover electrode 81 by the plating method (for example, electroless plating method).

Next, referring to FIG. 11N, the second resist mask 106 is removed. Next, referring to FIG. 11O, a portion, which is exposed from the pad electrode 71, of the second seed film 105 is removed. The unnecessary portions of the second seed film 105 may be removed by the etching method (for example, wet etching method).

In this step, the pad sidewall 74 of the pad electrode 71 is removed by an amount according to the thickness of the second seed film 105, and therefore the pad sidewall 74 recedes inward than the second peripheral wall 84 of the pad cover electrode 81. Hence, the second extension portion 86 of the pad cover electrode 81 is formed. Also, for this reason, the low-melting metal 90 covering the second extension portion 86 is formed.

Next, a portion, which is exposed from the pad electrode 71, of the second base barrier film 104 is removed. The unnecessary portions of the second base barrier film 104 may be removed by the etching method (for example, wet etching method). In this step, a portion, which is located directly under the pad electrode 71, of the second base barrier film 104 is removed by an amount according to the thickness of the second base barrier film 104, and therefore the second base barrier film 104 recedes inward than the pad sidewall 74 of the pad electrode 71. Hence, the pad barrier film 70 is formed.

Next, referring to FIG. 11P, the pad recessed portion 77 is formed at the pad lower end portion 76 of the pad electrode 71. The pad recessed portion 77 is formed by partially removing the pad lower end portion 76 of the pad electrode 71 by the etching method (for example, wet etching method). The size and the shape of the pad recessed portion 77 are regulated by adjusting the etching condition.

Next, referring to FIG. 11Q, the low-melting metal 90 is hemispherically formed through a reflow step. Thereafter, the wafer (not shown) is selectively cut, and a plurality of electronic components 1A are cut out. Hence, the electronic component 1A is manufactured.

Next, referring to FIG. 11R, the process of manufacturing the package 2A is performed. In the process of manufacturing the package 2A, the conductive plate 8 is separately prepared. Next, in an orientation in which the pad structure 65 is allowed to face the conductive plate 8, the electronic component 1A is arranged on the conductive plate 8 (die pad portion 9 and lead portion 10), and is mechanically and electrically connected to the conductive plate 8 via the low-melting metal 90.

Thereafter, referring to FIG. 11S, the molding resin 7 is supplied so as to seal the electronic component 1A and the conductive plate 8. Hence, the package 2A including the package body 3, the electronic component 1A, and the conductive plate 8 is manufactured.

As described above, the electronic component 1A includes the top insulation film 22 (to-be-covered object), the wiring electrode 31 (electrode), and the underlay resin film 60 (resin film). The wiring electrode 31 has the wiring upper end corner portion 38 that covers the top insulation film 22 and that is formed in a round shape. The underlay resin film 60 covers the wiring upper end corner portion 38 of the wiring electrode 31 on the top insulation film 22.

This structure makes it possible to relax stress that is generated near the wiring upper end corner portion 38 and that results from a rise in temperature. This makes it possible to suppress the peeling-off of the underlay resin film 60 or a crack in the underlay resin film 60 that is caused by the stress. Therefore, it is possible to provide the electronic component 1A that is capable of improving reliability.

The electronic component 1A includes the wiring cover electrode 41 that includes a conductor differing from the wiring electrode 31 and that covers the wiring upper end corner portion 38 of the wiring electrode 31. In this case, the underlay resin film 60 covers the wiring upper end corner portion 38 of the wiring electrode 31 across the wiring cover electrode 41. This structure makes it possible to relax stress generated in the wiring cover electrode 41 near the wiring upper end corner portion 38. Hence, it is possible to suppress the peeling-off of the underlay resin film 60 or a crack in the underlay resin film 60 that is caused by the stress generated in the wiring cover electrode 41.

In this case, preferably, the wiring cover electrode 41 includes the round portion 45 curved along the wiring upper end corner portion 38. This structure makes it possible to relax stress generated in the wiring cover electrode 41 with the round portion 45. Preferably, the wiring cover electrode 41 has the first extension portion 46 that projects outward than the wiring upper end corner portion 38 so as to face the top insulation film 22. This structure makes it possible to relax stress generated in the wiring cover electrode 41 in a structure in which the wiring cover electrode 41 has the first extension portion 46 with the round portion 45.

Preferably, the first extension portion 46 includes a portion that is placed closer to the top insulation film 22 than the wiring upper surface 33 of the wiring electrode 31. Preferably, the underlay resin film 60 exposes an inward portion of the wiring cover electrode 41. Preferably, the wiring cover electrode 41 includes the first metal film 47 including an Ni-based metal covering the wiring electrode 31. Preferably, the wiring cover electrode 41 includes the second metal film 48 that includes a Pd-based metal and that covers the first metal film 47. Preferably, the wiring cover electrode 41 is thinner than the wiring electrode 31.

Preferably, the wiring electrode 31 has the wiring sidewall 34 placed on the top insulation film 22, and has the wiring recessed portion 37 that is inwardly hollowed in the wiring lower end portion 36 of the wiring sidewall 34. This structure makes it possible to relax stress, which is generated near the wiring lower end portion 36 of the wiring electrode 31 and which is caused by a rise in temperature, with the wiring recessed portion 37. This makes it possible to suppress a crack in the top insulation film 22 that is caused by this stress.

Preferably, the electronic component 1A includes the wiring barrier film 30 covering the top insulation film 22. In this case, preferably, the wiring electrode 31 is formed on the wiring barrier film 30. This structure makes it possible to relax stress applied from the wiring electrode 31 onto the top insulation film 22 with the wiring barrier film 30. In this case, preferably, the wiring barrier film 30 has a thermal expansion coefficient lower than the thermal expansion coefficient of the wiring electrode 31.

This structure makes it possible to make a deformation amount of the wiring barrier film 30 caused by thermal expansion smaller than a deformation amount of the wiring electrode 31 by caused thermal expansion. Particularly, in a case in which the wiring barrier film 30 has a rigidity modulus higher than the rigidity modulus of the wiring electrode 31, it is possible to appropriately reduce the deformation amount of the wiring barrier film 30. This makes it possible to appropriately suppress stress onto the top insulation film 22. In this structure, it is possible to appropriately suppress stress generated near the wiring lower end portion 36 of the wiring electrode 31 by forming the wiring recessed portion 37 that exposes the wiring barrier film 30.

The wiring recessed portion 37 may have a width (first vertical width W1) exceeding the thickness of the wiring barrier film 30. Preferably, the top insulation film 22 includes an inorganic insulation film, and the wiring electrode 31 covers an inorganic insulation film. Preferably, the electronic component 1A includes the pad electrode 71 arranged on the wiring electrode 31 so as to be electrically connected to the wiring electrode 31.

The underlay resin film 60 is made of an organic film, and thus has the property of more easily undergoing elastic deformation than. Therefore, when the pad electrode 71 covering the underlay resin film 60 is formed, the stress of the pad electrode 71 is considered not to be a problem since the stress of the pad electrode 71 can be absorbed by the underlay resin film 60. However, the thickening (i.e., reduction in resistance) of the pad electrode 71 has been promoted in response to market demand, and the stress of the pad electrode 71 onto the underlay resin film 60 has no longer become ignored.

On this point, the electronic component 1A includes the underlay resin film 60 and the pad electrode 71. The pad electrode 71 covers the underlay resin film 60, and has the pad sidewall 74 placed on the underlay resin film 60. The pad electrode 71 has the pad recessed portion 77 that is hollowed inward than the pad upper end portion 75 of the pad sidewall 74 in the pad lower end portion 76 of the pad sidewall 74.

This structure makes it possible to relax stress, which is generated near the pad lower end portion 76 and which is caused by a rise in temperature, with the pad recessed portion 77. This makes it possible to suppress the peeling-off of the underlay resin film 60 or a crack in the underlay resin film 60 that is caused by the stress. Therefore, it is possible to provide the electronic component 1A that is capable of improving reliability.

Preferably, the pad electrode 71 is thicker than the underlay resin film 60 (sixth thickness T6). Preferably, the pad recessed portion 77 is formed at a portion, which is located closer to the underlay resin film 60 than an intermediate portion of the pad sidewall 74, of the pad electrode 71. This structure makes it possible to relax stress near the pad lower end portion 76. Also, it is possible to reduce a removal portion of the pad electrode 71, and therefore it is possible to suppress a rise in resistance of the pad electrode 71 that is caused by the pad recessed portion 77.

Preferably, the electronic component 1A includes the pad barrier film 70 covering the underlay resin film 60. In this case, preferably, the pad electrode 71 covers the underlay resin film 60 with the pad barrier film 70 between the pad electrode 71 and the underlay resin film 60. This structure makes it possible to relax stress applied from the pad electrode 71 onto the underlay resin film 60 with the pad barrier film 70.

Preferably, the pad barrier film 70 has a thermal expansion coefficient lower than the thermal expansion coefficient of the pad electrode 71. This structure makes it possible to make a deformation amount of the pad barrier film 70 caused by thermal expansion smaller than a deformation amount of the pad electrode 71 caused by thermal expansion. Particularly, in a case in which the pad barrier film 70 has a rigidity modulus higher than the rigidity modulus of the pad electrode 71, it is possible to appropriately reduce the deformation amount of the pad barrier film 70.

This makes it possible to appropriately suppress stress onto the underlay resin film 60. Also, in this structure, it is possible to appropriately suppress stress generated near the pad lower end portion 76 of the pad electrode 71 by forming the pad recessed portion 77 that exposes the pad barrier film 70. The pad recessed portion 77 may have a width (second vertical width W4) exceeding the thickness of the pad barrier film 70.

Preferably, the electronic component 1A includes the top insulation film 22 (inorganic insulation film) and the top wiring 25 (wiring) covering the top insulation film 22. In this case, preferably, the underlay resin film 60 covers the top wiring 25 so as to partially expose the top wiring 25. Also, preferably, the pad electrode 71 is connected to the top wiring 25 so as to cover the underlay resin film 60.

Preferably, the pad electrode 71 is erected in a pillar shape on the top wiring 25. Preferably, the pad electrode 71 is thicker than the top wiring 25. Preferably, the underlay resin film 60 has an elastic modulus lower than the top insulation film 22. Preferably, the electronic component 1A includes the wiring barrier film 30 covering the top insulation film 22. In this case, preferably, the top wiring 25 covers the top insulation film 22 with the wiring barrier film 30 between the top wiring 25 and the top insulation film 22.

Preferably, the top wiring 25 has the wiring upper end corner portion 38 formed in a round shape. In this case, preferably, the underlay resin film 60 covers the wiring upper end corner portion 38. This structure makes it possible to protect the top wiring 25 with the underlay resin film 60 while suppressing the peeling-off of the underlay resin film 60 or a crack in the underlay resin film 60. Also, it is possible to form the pad electrode 71 covering the underlay resin film 60 on the underlay resin film 60 having excellent film-forming properties.

The pad electrode 71 suppresses the peeling-off of the underlay resin film 60 or a crack in the underlay resin film 60 on the top wiring 25 with the pad recessed portion 77. This makes it possible to appropriately form the underlay resin film 60 in a structure including the top wiring 25 and the pad electrode 71. Preferably, the pad electrode 71 is electrically connected to the top wiring 25 at a distance from the wiring upper end corner portion 38. This structure makes it possible to prevent stress caused by the pad electrode 71 from occurring near the wiring upper end corner portion 38.

Preferably, the electronic component 1A includes the wiring cover electrode 41 that includes a conductor differing from the top wiring 25 and that covers the top wiring 25. In this case, preferably, the underlay resin film 60 covers the top wiring 25 with the wiring cover electrode 41 between the underlay resin film 60 and the top wiring 25. Also, preferably, the pad electrode 71 is electrically connected to the top wiring 25 via the wiring cover electrode 41. Preferably, the wiring cover electrode 41 has the first extension portion 46 that extends outwardly from the top wiring 25.

Preferably, the electronic component 1A includes the pad cover electrode 81 that includes a conductor differing from the pad electrode 71 and that covers the pad electrode 71. Preferably, the pad cover electrode 81 has the second extension portion 86 that extends outwardly from the pad electrode 71. Preferably, the low-melting metal 90 covering the pad cover electrode 81 is further included. Preferably, the low-melting metal 90 covers the second extension portion 86 of the pad cover electrode 81. Preferably, the low-melting metal 90 has the bulge portion 91 that projects outward than the pad electrode 71.

Preferably, the electronic component 1A further includes the overlay resin 95 covering the pad sidewall 74 of the pad electrode 71. Preferably, the overlay resin 95 fills the pad recessed portion 77 of the pad electrode 71. In this case, preferably, the overlay resin 95 comes into contact with the underlay resin film 60, with the pad barrier film 70, and with the pad electrode 71 in the pad recessed portion 77.

Preferably, the top wiring 25 includes a Cu-based metal. Preferably, the wiring barrier film 30 includes a Ti-based metal film. Preferably, the pad electrode 71 includes a Cu-based metal. Preferably, the pad barrier film 70 includes a Ti-based metal film. Preferably, the underlay resin film 60 includes a photosensitive resin. Particularly preferably, the underlay resin film 60 includes a phenol resin. Preferably, the overlay resin 95 includes a thermosetting resin. Preferably, the overlay resin 95 includes a matrix resin and fillers.

Preferably, the pad electrode 71 is configured not to be electrically connected to a bonding wire. The electronic component 1A may be incorporated into the package 2A. The package 2A includes the package body 3, the conductive plate 8, and the electronic component 1A. The package body 3 includes the molding resin 7. The conductive plate 8 is arranged inside the package body 3 so as to be exposed from the package body 3.

The electronic component 1A is arranged inside the package body 3, and is electrically connected to the conductive plate 8. The thus formed structure makes it possible to appropriately and electrically connect the pad electrode 71 to the conductive plate 8. Therefore, it is possible to provide the package 2A that is capable of improving reliability. In this case, the overlay resin 95 may be formed by a part of the molding resin 7.

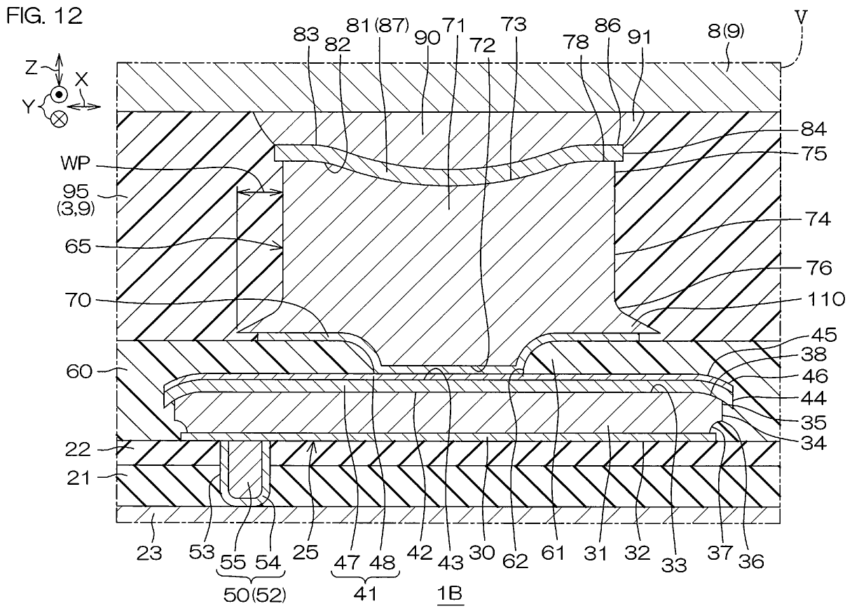

FIG. 12 corresponds to FIG. 5, and is a cross-sectional view showing an electronic component 1B according to a second embodiment. Referring to FIG. 12, in this embodiment, the pad electrode 71 has the pad sidewall 74 placed on the pad barrier film 70. In other words, the pad sidewall 74 is formed at a distance from the peripheral edge portion of the pad barrier film 70 to an inward portion of the pad barrier film 70. As a matter of course, the pad sidewall 74 may be placed in a region outside the pad barrier film 70 in the same way as in the first embodiment.

In this embodiment, the pad electrode 71 has a projection portion 110, instead of the pad recessed portion 77, in the pad lower end portion 76. The projection portion 110 protrudes from the pad lower end portion 76 toward the outside of the pad electrode 71, and forms an uneven portion at the pad lower end portion 76. The projection portion 110 projects outward than the peripheral edge portion of the pad barrier film 70 along the underlay resin film 60 so as to face the underlay resin film 60 without the pad barrier film 70 between the projection portion 110 and the underlay resin film 60 in the laminated direction.

In other words, the projection portion 110 includes a forward end portion placed outward from the peripheral edge of the pad barrier film 70 and a base end portion placed inward from the peripheral edge of the pad barrier film 70. The projection portion 110 includes a portion that forms a gap between the underlay resin film 60 and the pad barrier film 70. The projection portion 110 is formed at a distance from the intermediate portion of the pad sidewall 74 toward the top wiring 25 side. The projection portion 110 is formed in a tapered shape in which the thickness gradually becomes smaller from the pad sidewall 74 toward the forward end portion in a cross-sectional view. Hence, the projection portion 110 has a forward end portion having a pointed shape at an acute angle.

The projection portion 110 includes a portion that has a thickness exceeding the seventh thickness T7 of the pad barrier film 70 in the laminated direction. In detail, a portion (base end portion on the pad sidewall 74 side), which is placed on the pad barrier film 70, of the projection portion 110 has a thickness exceeding the seventh thickness T7 of the pad barrier film 70. On the other hand, a portion (forward end portion), which is placed outside the pad barrier film 70, of the projection portion 110 has a thickness less than the seventh thickness T7 of the pad barrier film 70.

The projection portion 110 has a projection width WP exceeding the seventh thickness T7 of the pad barrier film 70 with respect to the direction perpendicular to the laminated direction. The projection width WP is the thickness of the pad electrode 71 on the basis (zero point) of the pad sidewall 74. The projection width WP may be not less than 0.05 μm and not more than 10 μm. Preferably, the projection width WP is not less than 0.5 μm and not more than 5 μm.

In this embodiment, the second extension portion 86 of the pad cover electrode 81 faces the projection portion 110 of the pad electrode 71 in the laminated direction. In this embodiment, the second extension width W6 of the second extension portion 86 has a projection width less than the projection width WP of the projection portion 110 with respect to the direction perpendicular to the laminated direction. As a matter of course, the second extension width W6 may exceed the projection width WP.

In this embodiment, the bulge portion 91 of the low-melting metal 90 faces the projection portion 110 of the pad electrode 71 in the laminated direction. The bulge portion 91 of the low-melting metal 90 faces the projection portion 110 without the second extension portion 86 between the bulge portion 91 and the projection portion 110. Where the second extension width W6 of the second extension portion 86 exceeds the projection width WP, the bulge portion 91 may face the underlay resin film 60 without the projection portion 110 between the bulge portion 91 and the underlay resin film 60.

The overlay resin 95 covers the pad sidewall 74 of the pad electrode 71 in the same way as in the first embodiment. In this embodiment, the overlay resin 95 fills a gap between the underlay resin film 60 and the projection portion 110 in the pad lower end portion 76, and covers the projection portion 110. The overlay resin 95 comes into contact with the underlay resin film 60, with the pad barrier film 70, and with the projection portion 110 in the gap between the underlay resin film 60 and the projection portion 110.

In other words, the overlay resin 95 sandwiches the projection portion 110 from the up-down direction directly above and directly under the projection portion 110. Also, the overlay resin 95 has a portion facing the pad barrier film 70 on the projection portion 110 and a portion facing the outside of the pad barrier film 70 across the projection portion 110.

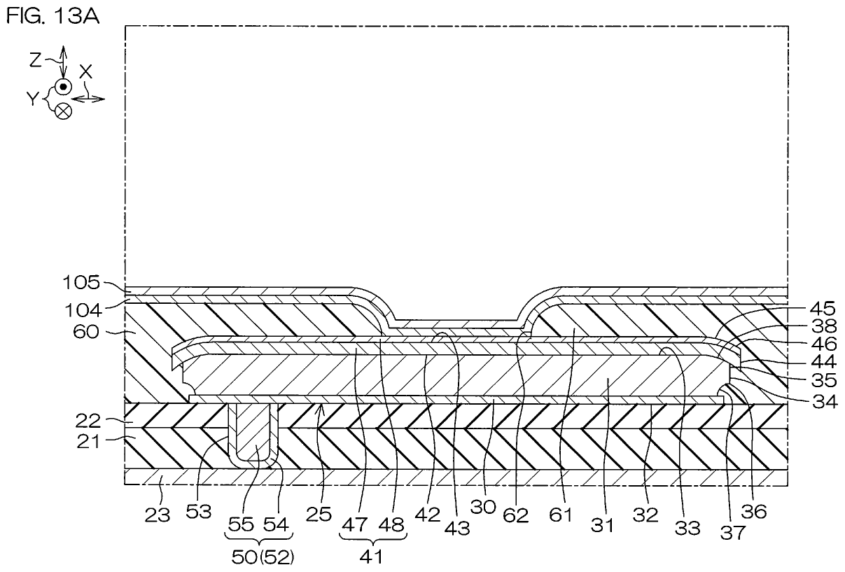

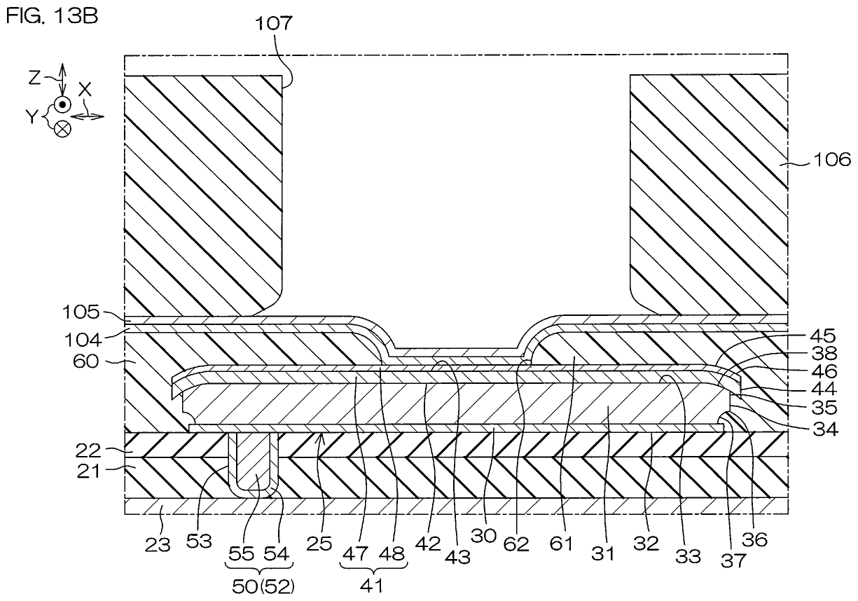

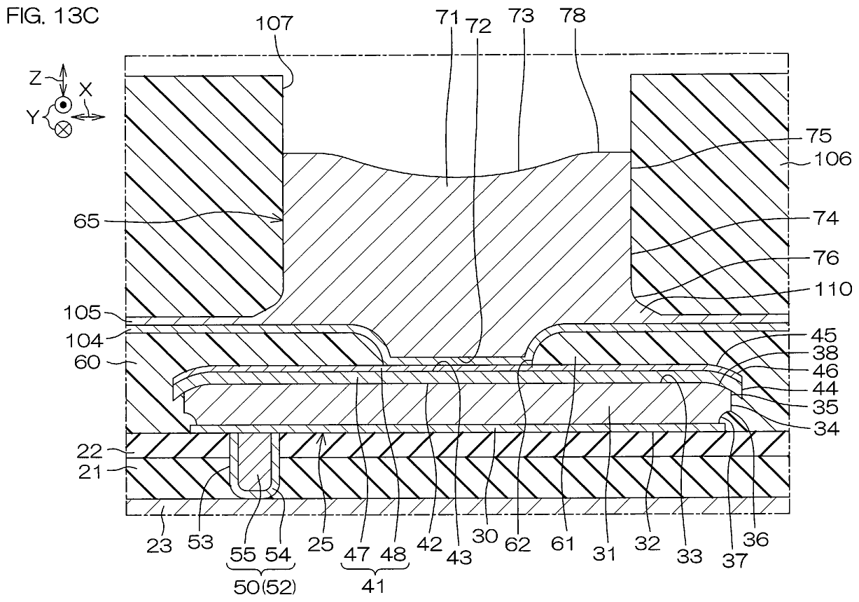

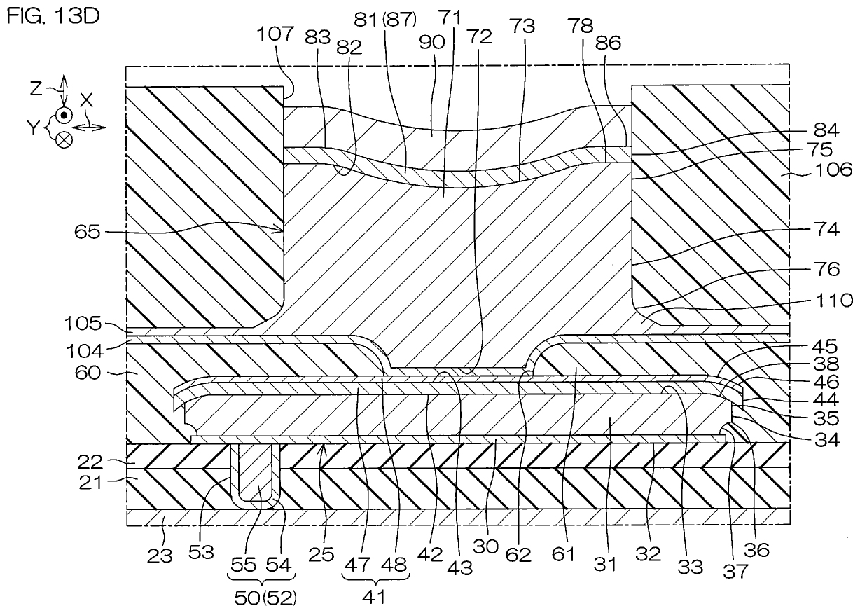

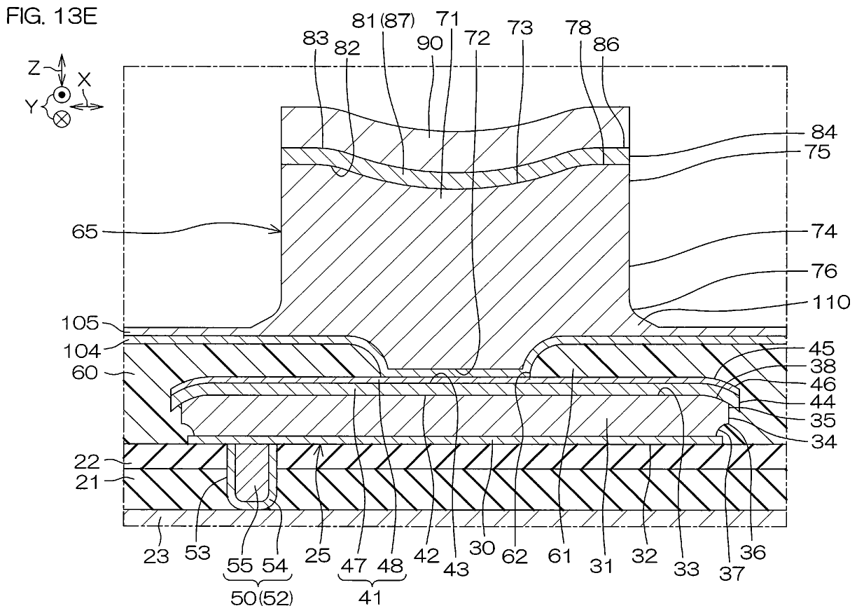

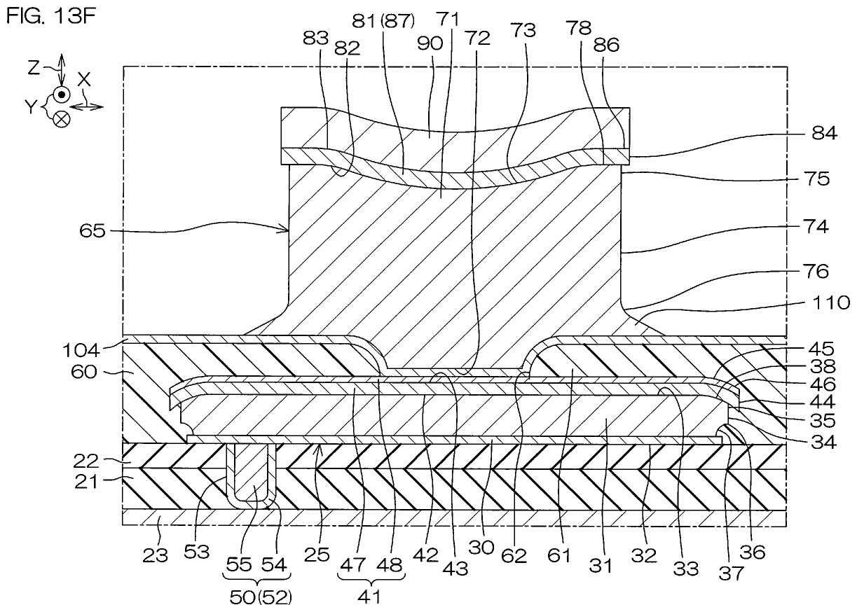

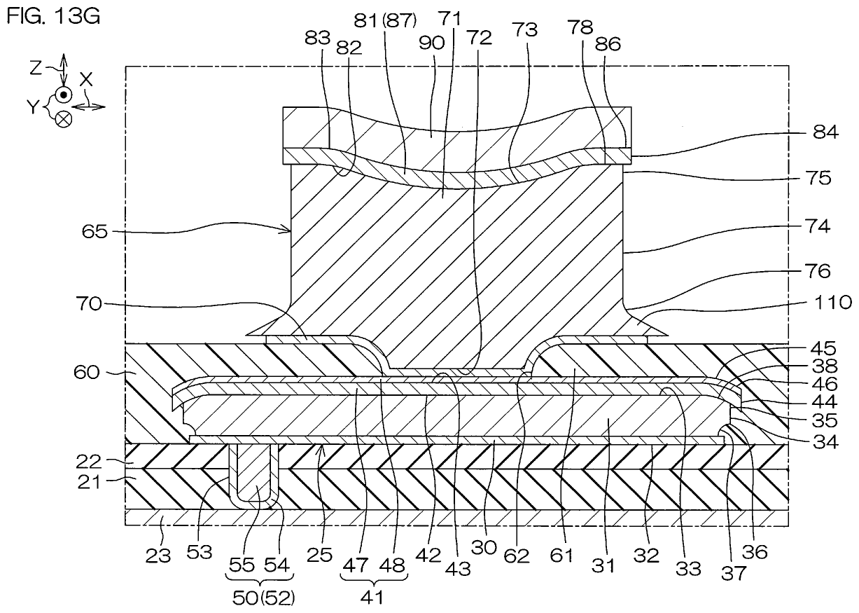

FIG. 13A to FIG. 13G are cross-sectional views each of which shows an example of a process of manufacturing the electronic component 1B of FIG. 12. First, referring to FIG. 13A, the second base barrier film 104 and the second seed film 105 are formed through the steps of FIG. 11A to FIG. 11J.

Next, referring to FIG. 13B, the second resist mask 106 having a predetermined pattern is formed on the second seed film 105. The second resist mask 106 has the second opening 107 that exposes a region in which the pad electrode 71 is to be formed. In this step, baking conditions (baking temperature, baking period of time, etc.) with respect to the second resist mask 106 after exposure are adjusted, and adhesive properties of the second resist mask 106 with respect to the second seed film 105 are reduced.

Next, referring to FIG. 13C, the pad electrode 71 is formed on the second seed film 105. The pad electrode 71 is formed so as to be united integrally with the second seed film 105 by the plating method (for example, electrolytic plating method). In this step, the second seed film 105 is immersed in a plating solution that contains surfactant.

In this step, a plating solution is supplied between the second seed film 105 and the second resist mask 106 in the lower end of the second opening 107, and a part of the pad electrode 71 is allowed to protuberantly grow up between the second seed film 105 and the second resist mask 106. Hence, the projection portion 110 of the pad electrode 71 is formed between the second seed film 105 and the second resist mask 106. The pad electrode 71 is formed to a height position that is halfway in the thickness direction of the second resist mask 106.

Next, referring to FIG. 13D, the pad cover electrode 81 and the low-melting metal 90 are formed on the pad electrode 71 through the same step as in FIG. 11M mentioned above. Next, referring to FIG. 13E, the second resist mask 106 is removed. Next, referring to FIG. 13F, the unnecessary portions of the second seed film 105 are removed so that the projection portion 110 remains through the same step as in FIG. 11O mentioned above. Hence, the pad electrode 71 having the projection portion 110 is formed.

Next, referring to FIG. 13G, a portion, which is exposed from the projection portion 110 of the pad electrode 71, of the second base barrier film 104 is removed. The unnecessary portions of the second base barrier film 104 are removed by the etching method (for example, wet etching method).

In this step, a portion, which is located directly under the projection portion 110, of the second base barrier film 104 is removed by an amount according to the thickness of the second base barrier film 104, and therefore the second base barrier film 104 recedes inward than the projection portion 110. Hence, the pad barrier film 70 is formed. Steps subsequent to this are performed in the same way as in the first embodiment.

As described above, the electronic component 1B includes the underlay resin film 60 and the pad electrode 71. The pad electrode 71 covers the underlay resin film 60, and has the pad sidewall 74 placed on the underlay resin film 60. The pad electrode 71 has the projection portion 110 that protrudes outward than the pad upper end portion 75 of the pad sidewall 74 in the pad lower end portion 76 of the pad sidewall 74.

This structure makes it possible to relax stress, which is generated near the pad lower end portion 76 and which is caused by a rise in temperature, with the projection portion 110. This makes it possible to suppress the peeling-off of the underlay resin film 60 or a crack in the underlay resin film 60 that is caused by the stress. Therefore, it is possible to provide the electronic component 1B that is capable of improving reliability.

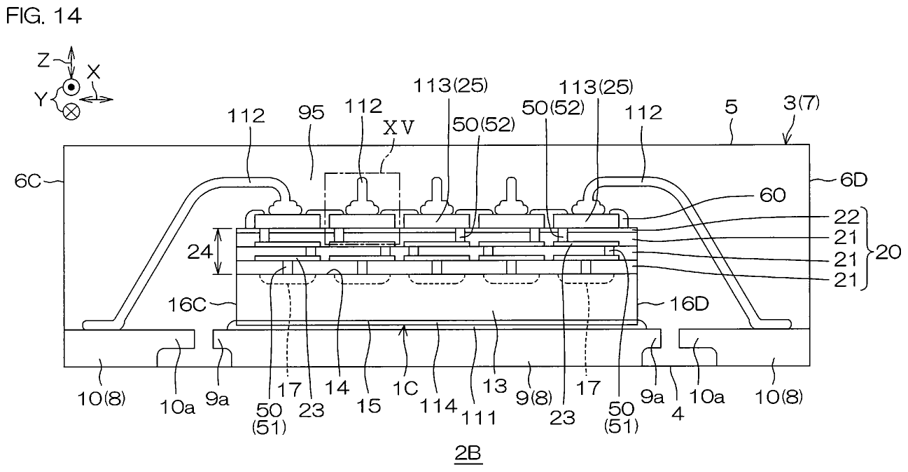

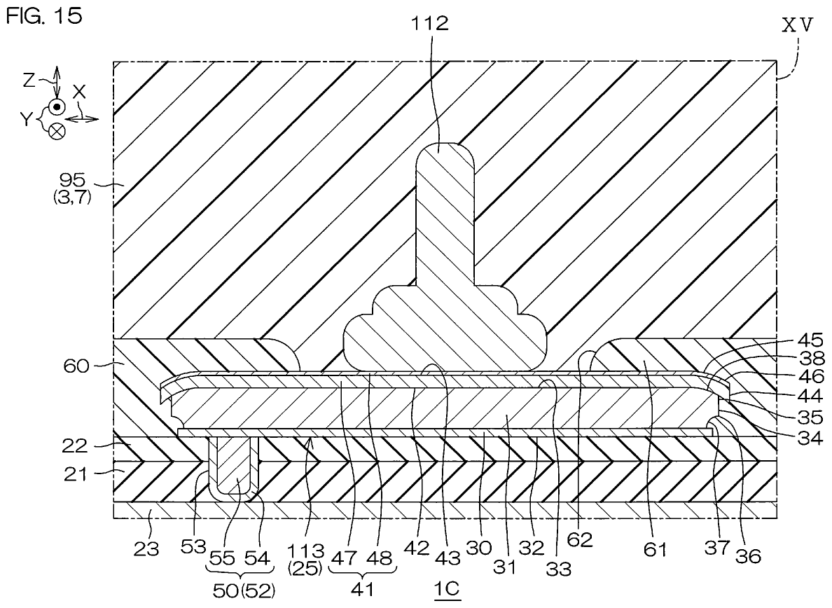

FIG. 14 corresponds to FIG. 4, and is a cross-sectional view showing a package 2B in which an electronic component 1C according to a third embodiment is mounted. FIG. 15 is an enlarged view of a region XV of FIG. 14. The electronic component 1C is a device that fulfills the same effect as in the first embodiment with respect to the top wiring 25.

The electronic components 1A and 1B according to the first and second embodiments were components of a flip chip connection type. On the other hand, the electronic component 1C according to the third embodiment is a component of a wire bonding connection type. In this embodiment, the package 2B includes the package body 3, the conductive plate 8, the electronic component 1C, a conductive joining material 111, and a plurality of wires 112. The package body 3 and the conductive plate 8 are formed in the same way as in the first embodiment.

The electronic component 1C does not have the pad structure 65. Therefore, the pad opening 62 of the underlay resin film 60 exposes a part of the top wiring 25 as a pad electrode 113. The electronic component 1C includes a main surface electrode 114 covering the second main surface 15 of the semiconductor chip 13. The main surface electrode 114 covers the whole area of the second main surface 15, and is continuous with the first to fourth side surfaces 16A to 16D. The main surface electrode 114 makes an ohmic contact with the semiconductor chip 13.

The main surface electrode 114 may include at least one among a Ti film, an Ni film, a Pd film, an Au film, and an Ag film. The main surface electrode 114 is merely required to include a Ti film with which at least the second main surface 15 is directly covered, and the presence or absence of the Ni film, the Pd film, the Au film, and the Ag film and the order of laminated layers are arbitrary.

As an example, the main surface electrode 114 may include a Ti film, an Ni film, a Pd film, and an Au film that are laminated in that order from the second main surface 15 side. The main surface electrode 114 is formed by the sputtering method and/or the vapor deposition method at an arbitrary timing before the wafer dicing step in the manufacturing process mentioned above.

The electronic component 1C is arranged on the conductive plate 8 in an orientation in which the main surface electrode 114 is allowed to face the conductive plate 8 (in this embodiment, die pad portion 9). The conductive joining material 111 is interposed between the main surface electrode 114 and the conductive plate 8, and mechanically and electrically connects the main surface electrode 114 and the conductive plate 8. The conductive joining material 111 may include at least either one of conductive paste and solder.

The wires 112 include at least one among an aluminum wire, a copper wire, and a gold wire. Each of the wires 112 connects a corresponding one of the lead portions 10 to a corresponding one of the pad electrodes 113. In this embodiment, the molding resin 7 (overlay resin 95 film) covers the pad electrodes 113 and the wires 112 on the underlay resin film 60.

The aforementioned embodiments are performed in still other modes. For example, QFN (Quad Flat Non-leaded) is shown as one form of the packages 2A and 2B as described in each of the aforementioned embodiments. However, the packages 2A and 2B may be SOP (Small Outline Package), DFP (Dual Flat Package), DIP (Dual Inline Package), QFP (Quad Flat Package), SIP (Single Inline Package), SOJ (Small Outline J-leaded Package), or TO (Transistor Outline), or may have various forms similar to these packages.

Also, the package 2A may be a wafer level chip size package that includes the molding resin 7 covering the outer surface of the electronic component 1A or 1B without the conductive plate 8 so as to expose the pad structure 65 (low-melting metal 90). In other words, the electronic component 1A or 1B may be a wafer level chip size package that includes the overlay resin 95 covering the semiconductor chip 13, the insulation layer (multilayer wiring structure 24), the underlay resin film 60, and the pad structure 65 so as to expose a part of the pad structure 65 (low-melting metal 90).

Characteristic examples extracted from this description and from the drawings are hereinafter shown. The electronic component capable of improving reliability is hereinafter provided. Hereinafter, alphanumeric characters in parentheses represent corresponding components in the aforementioned embodiments, and yet this representation does not denote that the scope of each Clause is limited to the embodiments. “Electronic component” according to the following Clauses may be replaced by “Semiconductor device,” “Integrated circuit device,” “Package,” “Electronic package,” “Semiconductor package,” “Module,” “Electronic module,” “Semiconductor module,” “Wafer level chip size package,” etc.

[A1] An electronic component (1A to 1C) comprising: an underlay resin (60); and a pad electrode (71) that has a sidewall (74) located on the underlay resin (60) and an uneven portion (77/110) formed at a lower end portion of the sidewall (74).

[A2] The electronic component (1A to 1C) according to A1, wherein the uneven portion (77/110) consists of a recessed portion (77) that is inwardly hollowed in the lower end portion of the sidewall (74).

[A3] The electronic component (1A to 1C) according to A2, further comprising: a pad barrier film (70) covering the underlay resin (60); wherein the pad electrode (71) covers the underlay resin (60) with the pad barrier film (70) between the pad electrode (71) and the underlay resin (60).

[A4] The electronic component (1A to 1C) according to A3, wherein the recessed portion (77) has an upper end portion located outward from a peripheral edge of the pad barrier film (70) and a lower end portion located inward from the peripheral edge of the pad barrier film (70), and exposes a peripheral edge portion of the pad barrier film (70).

[A5] The electronic component (1A to 1C) according to A1, wherein the uneven portion (77/110) consists of a projection portion (110) that outwardly protrudes so as to face the underlay resin (60) in the lower end portion of the sidewall (74).

[A6] The electronic component (1A to 1C) according to A5, further comprising: a pad barrier film (70) covering the underlay resin (60); wherein the pad electrode (71) covers the underlay resin (60) with the pad barrier film (70) between the pad electrode (71) and the underlay resin (60).

[A7] The electronic component (1A to 1C) according to A6, wherein the projection portion has a forward end portion located outward from the peripheral edge of the pad barrier film (70) and a base end portion located inward from the peripheral edge of the pad barrier film (70), and forms a gap between the underlay resin (60) and the pad barrier film (70).

[A8] The electronic component (1A to 1C) according to any one of A1 to A7, wherein the pad electrode (71) is not to be electrically connected to a bonding wire (112).

[A9] The electronic component (1A to 1C) according to any one of A1 to A8, wherein the pad electrode (71) is thicker than the underlay resin (60).

[A10] The electronic component (1A to 1C) according to any one of A1 to A9, further comprising: an inorganic insulation film (22); and a wiring electrode (31) covering the inorganic insulation film (22); wherein the underlay resin (60) covers the wiring electrode (31) so as to partially expose the wiring electrode (31), and the pad electrode (71) covers the wiring electrode (31) and the underlay resin (60).

[A11] The electronic component (1A to 1C) according to A10, wherein the pad electrode (71) is thicker than the wiring electrode (31).

[A12] The electronic component (1A to 1C) according to A10 or A11, further comprising: a wiring barrier film (30) covering the inorganic insulation film (22); wherein the wiring electrode (31) covers the inorganic insulation film (22) with the wiring barrier film (30) between the wiring electrode and the inorganic (31) insulation film (22).

[A13] The electronic component (1A to 1C) according to any one of A10 to A12, wherein the wiring electrode (31) has an upper end corner portion (38) formed in a round shape, and the underlay resin (60) covers the upper end corner portion (38).

[A14] The electronic component (1A to 1C) according to A13, wherein the pad electrode (71) is electrically connected to the wiring electrode (31) at a distance from the upper end corner portion (38).

[A15] The electronic component (1A to 1C) according to any one of A10 to A14, further comprising: a wiring cover electrode (41) that covers the wiring electrode (31); wherein the underlay resin (60) covers the wiring electrode (31) with the wiring cover electrode (41) between the underlay resin (60) and the wiring electrode (31), and the pad electrode (71) is electrically connected to the wiring electrode (31) via the wiring cover electrode (41).

[A16] The electronic component (1A to 1C) according to any one of A1 to A15, further comprising: a pad cover electrode (81) that covers the pad electrode (71).

[A17] The electronic component (1A to 1C) according to A16, wherein the pad cover electrode (81) projects outward than the pad electrode (71).

[A18] The electronic component (1A to 1C) according to A16 or A17, further comprising: a low-melting metal (90) that covers the pad cover electrode (81).

[A19] The electronic component (1A to 1C) according to any one of A1 to A18, further comprising: an overlay resin (95) that covers the sidewall (74) of the pad electrode (71).

[A20] The electronic component (1A to 1C) according to A19, wherein the underlay resin (60) is made of a photosensitive resin, and the overlay resin (95) is made of a thermosetting resin.

[A21] An electronic component (1A to 1C) comprising: an underlay resin (60); and a pad electrode (71) that has a sidewall (74) located on the underlay resin (60) and a recessed portion (77) inwardly hollowed in a lower end portion (76) of the sidewall (74).

[A22] An electronic component (1A to 1C) comprising: an underlay resin (60); and a pad electrode (71) that has a sidewall (74) located on the underlay resin (60) and a projection portion (110) that outwardly protrudes so as to face the underlay resin (60) in a lower end portion (76) of the sidewall (74).

[B1] An electronic component (1A to 1C) comprising: a to-be-covered object (20, 22, 24); an electrode (31) covering the to-be-covered object (20, 22, 24) and having an upper end corner portion (38) formed in a round shape; and an organic film (60) covering the upper end corner portion (38) of the electrode (31) on the to-be-covered object (20, 22, 24).

[B2] The electronic component (1A to 1C) according to B1, further comprising: a cover electrode (41) covering the upper end corner portion (38) of the electrode (31); wherein the organic film (60) covers the upper end corner portion (38) with the cover electrode (41) between the organic film (60) and the upper end corner portion (38).

[B3] The electronic component (1A to 1C) according to B2, wherein the cover electrode (41) includes a round portion (45) curved along the upper end corner portion (38).

[B4] The electronic component (1A to 1C) according to B2 or B3, wherein the cover electrode (41) has an extension portion (46) that extends outward from the upper end corner portion (38) of the electrode (31) so as to face the to-be-covered object (20, 22, 24).

[B5] The electronic component (1A to 1C) according to B4, wherein the extension portion (46) includes a portion located closer to the to-be-covered object (20, 22, 24) than an upper surface of the electrode (31).

[B6] The electronic component (1A to 1C) according to any one of B2 to B5, wherein the organic film (60) exposes an inward portion of the cover electrode (41).

[B7] The electronic component (1A to 1C) according to any one of B2 to B6, wherein the cover electrode (41) includes a conductor differing from that of the electrode (31).

[B8] The electronic component (1A to 1C) according to B7, wherein the cover electrode (41) has a laminated structure in which a plurality of metal films are laminated.

[B9] The electronic component (1A to 1C) according to any one of B2 to B8, wherein the cover electrode (41) is thinner than the electrode (31).

[B10] The electronic component (1A to 1C) according to any one of B1 to B9, wherein the electrode (31) has a sidewall (34) located on the to-be-covered object (20, 22, 24), and has a recessed portion (37) that is inwardly hollowed in a lower end portion (36) of the sidewall (34).

[B11] The electronic component (1A to 1C) according to any one of B1 to B10, further comprising: a barrier film (30) covering the to-be-covered object (20, 22, 24); wherein the electrode (31) covers the to-be-covered object (20, 22, 24) with the barrier film (30) between the electrode (31) and the to-be-covered object (20, 22, 24).

[B12] The electronic component (1A to 1C) according to any one of B1 to B11, wherein the to-be-covered object (20, 22, 24) includes an inorganic film (22), and the electrode (31) covers the inorganic film (22).

[B13] The electronic component (1A to 1C) according to any one of B1 to B12, further comprising: a pad electrode (71) arranged on the organic film (60) so as to be electrically connected to the electrode (31).

[B14] The electronic component (1A to 1C) according to any one of B1 to B13, wherein the to-be-covered object includes an insulation layer (20), and the electrode (31) covers the insulation layer (20).

[B15] The electronic component (1A to 1C) according to B14, further comprising: a wiring (23) arranged inside the insulation layer (20), wherein the electrode (31) is electrically connected to the wiring (23).

[B16] The electronic component (1A to 1C) according to any one of B1 to B15, wherein the electrode (31) is made of a Cu-based metal film, and the organic film (60) is made of a photosensitive resin.

[B17] An electronic component (1A to 1C) comprising: an inorganic insulation film (22); an electrode (31) covering the inorganic insulation film (22) and having an upper end corner portion (38) formed in a round shape; a first resin (60) covering the upper end corner portion (38); and a second resin (95) having a portion covering the upper end corner portion (38) with the first resin (60) between the portion of the second resin (95) and the upper end corner portion (38).

[B18] The electronic component (1A to 1C) according to B17, wherein the second resin (95) has a portion covering the inorganic insulation film (22) with the first resin (60) between the portion of the second resin (95) and the inorganic insulation film (22).

[B19] The electronic component (1A to 1C) according to B17 or B18, further comprising: a cover electrode (41) covering the upper end corner portion (38) of the electrode (31) and having a round portion (45) curved along the upper end corner portion (38); wherein the first resin (60) covers the upper end corner portion (38) with the cover electrode (41) between the first resin (60) and the upper end corner portion (38), and the second resin (95) covers the upper end corner portion (38) with both the cover electrode (41) and the first resin (60) between the second resin (95) and the upper end corner portion (38).

[B20] The electronic component (1A to 1C) according to any one of B17 to B19, wherein the electrode (31) has a sidewall (34) located on the to-be-covered object (20, 22, 24), and has a recessed portion (37) that is inwardly hollowed in a lower end portion (36) of the sidewall (34), and the first resin (60) fills the recessed portion (37).

Although the embodiments have been described in detail as above, these embodiments are merely concrete examples used to clarify the technical contents, and the present invention should not be understood by being limited to these concrete examples, and the scope of the present invention is limited by the appended Claims.

What is claimed is:

1. An electronic component comprising:
an underlay resin; and
a pad electrode that has a sidewall located on the underlay resin and an uneven portion formed at a lower end portion of the sidewall.

2. The electronic component according to claim 1,
wherein the uneven portion consists of a recessed portion that is inwardly hollowed in the lower end portion of the sidewall.

3. The electronic component according to claim 2, further comprising:
a pad barrier film covering the underlay resin;
wherein the pad electrode covers the underlay resin with the pad barrier film between the pad electrode and the underlay resin.

4. The electronic component according to claim 3,
wherein the recessed portion has an upper end portion located outward from a peripheral edge of the pad barrier film and a lower end portion located inward from the peripheral edge of the pad barrier film, and exposes a peripheral edge portion of the pad barrier film.

5. The electronic component according to claim 1,
wherein the uneven portion consists of a projection portion that outwardly protrudes so as to face the underlay resin in the lower end portion of the sidewall.

6. The electronic component according to claim 5, further comprising:
a pad barrier film covering the underlay resin;
wherein the pad electrode covers the underlay resin with the pad barrier film between the pad electrode and the underlay resin.

7. The electronic component according to claim 6,
wherein the projection portion has a forward end portion located outward from the peripheral edge of the pad barrier film and a base end portion located inward from the peripheral edge of the pad barrier film, and forms a gap between the underlay resin and the pad barrier film.

8. The electronic component according to claim 1,
wherein the pad electrode is not to be electrically connected to a bonding wire.

9. The electronic component according to claim 1,
wherein the pad electrode is thicker than the underlay resin.

10. The electronic component according to claim 1, further comprising:
an inorganic insulation film; and
a wiring electrode covering the inorganic insulation film;
wherein the underlay resin covers the wiring electrode so as to partially expose the wiring electrode, and
the pad electrode covers the wiring electrode and the underlay resin.

11. The electronic component according to claim 10,
wherein the pad electrode is thicker than the wiring electrode.

12. The electronic component according to claim 10, further comprising:
a wiring barrier film covering the inorganic insulation film;
wherein the wiring electrode covers the inorganic insulation film with the wiring barrier film between the wiring electrode and the inorganic insulation film.

13. The electronic component according to claim 10,
wherein the wiring electrode has an upper end corner portion formed in a round shape, and
the underlay resin covers the upper end corner portion.

14. The electronic component according to claim 13,
wherein the pad electrode is electrically connected to the wiring electrode at a distance from the upper end corner portion.

15. The electronic component according to claim 10, further comprising:
a wiring cover electrode that covers the wiring electrode;
wherein the underlay resin covers the wiring electrode with the wiring cover electrode between the underlay resin and the wiring electrode, and
the pad electrode is electrically connected to the wiring electrode via the wiring cover electrode.

16. The electronic component according to claim 1, further comprising:
a pad cover electrode that covers the pad electrode.

17. The electronic component according to claim 16,
wherein the pad cover electrode projects outward than the pad electrode.

18. The electronic component according to claim 16, further comprising:
a low-melting metal that covers the pad cover electrode.

19. The electronic component according to claim 1, further comprising:
an overlay resin that covers the sidewall of the pad electrode.

20. The electronic component according to claim 19,
wherein the underlay resin is made of a photosensitive resin, and
the overlay resin is made of a thermosetting resin.
